(19) United States
(12) Patent Application Publication
(10) Pub. No.: US 2025/0208787 A1
(43) Pub. Date: Jun. 26, 2025

(54) SEMICONDUCTOR MEMORY DEVICE

(71) Applicant: Kioxia Corporation, Tokyo (JP)

(72) Inventor: Koji HOSONO, Fujisawa Kanagawa (JP)

(73) Assignee: Kioxia Corporation, Tokyo (JP)

(21) Appl. No.: 19/074,324

(22) Filed: Mar. 8, 2025

Related U.S. Application Data
(63) Continuation of application No. PCT/JP2022/038255, filed on Oct. 13, 2022.

(51) Int. Cl. G06F 3/06

(52) U.S. Cl. CPC G06F 3/0655; G06F 3/0604; G06F 3/0679

(57) ABSTRACT

According to an embodiment, a semiconductor memory device includes a first chip, a second chip, and third chip. The first chip includes a first pillar including a first memory cell and a second memory cell coupled in series. The second chip includes a second pillar including a third memory cell and a fourth memory cell coupled in series. The third chip includes a row decoder to which a first word line, a second word line, and a third word line are coupled. The first word line is coupled to a gate of the first memory cell. The second word line is coupled to a gate of the third memory cell. The third word line is coupled to gates of the second memory cell and the fourth memory cell.

### CROSS-REFERENCE TO RELATED APPLICATIONS

This application is a Continuation Application of PCT Application No. PCT/JP2022/038255, filed Oct. 13, 2022, the entire contents of all of which are incorporated herein by reference.

### FIELD

Embodiments described herein relate generally to a semiconductor memory device.

### BACKGROUND

As a semiconductor memory device, a NAND flash memory is known.

### BRIEF DESCRIPTION OF THE DRAWINGS

FIG. 1 is a block diagram illustrating an overall configuration of a memory system including a semiconductor memory device according to a first embodiment.

FIG. 2 is a plan view illustrating a circuit configuration of a memory cell array included in the semiconductor memory device according to the first embodiment.

FIG. 3 is a perspective view illustrating the circuit configuration of the memory cell array included in the semiconductor memory device according to the first embodiment.

FIG. 4 is a circuit diagram of a row decoder included in the semiconductor memory device according to the first embodiment.

FIG. 5 is a cross-sectional view illustrating an arrangement of an array chip and a circuit chip included in the semiconductor memory device according to the first embodiment.

FIG. 6 is a perspective view illustrating the arrangement of the array chip and the circuit chip included in the semiconductor memory device according to the first embodiment.

FIG. 7 is a cross-sectional view of the memory cell array included in the semiconductor memory device according to the first embodiment.

FIG. 8 is a diagram illustrating a configuration of a block included in the semiconductor memory device according to the first embodiment, and a change in a write state of data by a sub-block erase operation.

FIG. 9 is a command sequence of a write operation in the semiconductor memory device according to the first embodiment.

FIG. 10 is a configuration diagram of a memory address in the semiconductor memory device according to the first embodiment.

FIG. 11 is a diagram illustrating a writing order of data based on the memory address shown in FIG. 10.

FIG. 12 is a diagram illustrating a configuration of a block in the semiconductor memory device according to the first embodiment and a change in a write state of data by a write operation of a sub-block SB1.

FIG. 13 is a timing chart illustrating a voltage of each interconnect in the write operation of the sub-block SB1 in the semiconductor memory device according to the first embodiment.

FIG. 14 is a diagram illustrating a configuration of a block in the semiconductor memory device according to the first embodiment and a change in a write state of data by a write operation of a sub-block SB0.

FIG. 15 is a timing chart illustrating a voltage of each interconnect in the write operation of the sub-block SB0 in the semiconductor memory device according to the first embodiment.

FIG. 16 is a cross-sectional view illustrating an arrangement of the array chip and the circuit chip included in the semiconductor memory device according to a first modification of the first embodiment.

FIG. 17 is a perspective view illustrating a circuit configuration of the memory cell array included in the semiconductor memory device according to the first modification of the first embodiment.

FIG. 18 is a circuit diagram of the row decoder included in the semiconductor memory device according to the first modification of the first embodiment.

FIG. 19 is a diagram illustrating a configuration of a block included in the semiconductor memory device according to the first modification of the first embodiment and a write state of data by a write operation of the sub-block SB1.

FIG. 20 is a diagram illustrating a configuration of a block included in the semiconductor memory device according to a second modification of the first embodiment and a write state of data by a write operation of the sub-block SB1.

FIG. 21 is a configuration diagram of a memory address in a semiconductor memory device according to the second embodiment.

FIG. 22 is a diagram illustrating a writing order of data based on the memory address shown in FIG. 21.

FIG. 23 is a diagram illustrating a configuration of a block included in the semiconductor memory device according to the second embodiment and a change in a write state of data by a write operation of a sub-block SB0.

FIG. 24 is a cross-sectional view of a memory cell array included in the semiconductor memory device according to a first modification of the second embodiment.

FIG. 25 is a diagram illustrating a configuration of a block included in the semiconductor memory device according to the first modification of the second embodiment and a change in a write state of data by a write operation of the sub-block SB0.

FIG. 26 is a cross-sectional view illustrating an arrangement of an array chip and a circuit chip included in the semiconductor memory device according to a second modification of the second embodiment.

FIG. 27 is a perspective view illustrating a circuit configuration of a memory cell array included in the semiconductor memory device according to a second modification of the second embodiment.

FIG. 28 is a diagram illustrating a configuration of a block included in the semiconductor memory device according to the second modification of the second embodiment and a change in a write state of data by a write operation of the sub-block SB0.

### DETAILED DESCRIPTION

In general, according to one embodiment, a semiconductor memory device includes a first chip, a second chip, and third chip. The first chip includes a first pillar including a first memory cell and a second memory cell coupled in series, a first bit line coupled to one end of the first pillar, and a first source line coupled to another end of the first pillar. The second chip includes a second pillar including a third memory cell and a fourth memory cell coupled in series, a second bit line coupled to one end of the second pillar, and a second source line coupled to another end of the second pillar. The third chip includes a sense amplifier to which the first bit line and the second bit line are commonly coupled and a row decoder to which a first word line, a second word line, and a third word line are coupled. The first word line is coupled to a gate of the first memory cell. The second word line is coupled to a gate of the third memory cell. The third word line is coupled to gates of the second memory cell and the fourth memory cell.

Hereinafter, embodiments will be described with reference to the drawings. In the following description, components having substantially the same functions and configurations are denoted by the same reference numerals. Redundant description may be omitted if unnecessary. In addition, each of the embodiments described below illustrates an apparatus and a method for embodying the technical idea of the embodiment. The technical idea of the embodiment does not specify the material, shape, structure, arrangement, and the like of the components as described below. Various modifications can be made to the technical idea of the embodiment without departing from the gist of the invention. These embodiments and modifications of the embodiments are included in the scope of the invention described in the claims and the equivalent thereof.

### 1. First Embodiment

A semiconductor memory device according to a first embodiment will be described.

### 1.1 Configuration

### 1.1.1 Overall Configuration of Semiconductor Memory Device

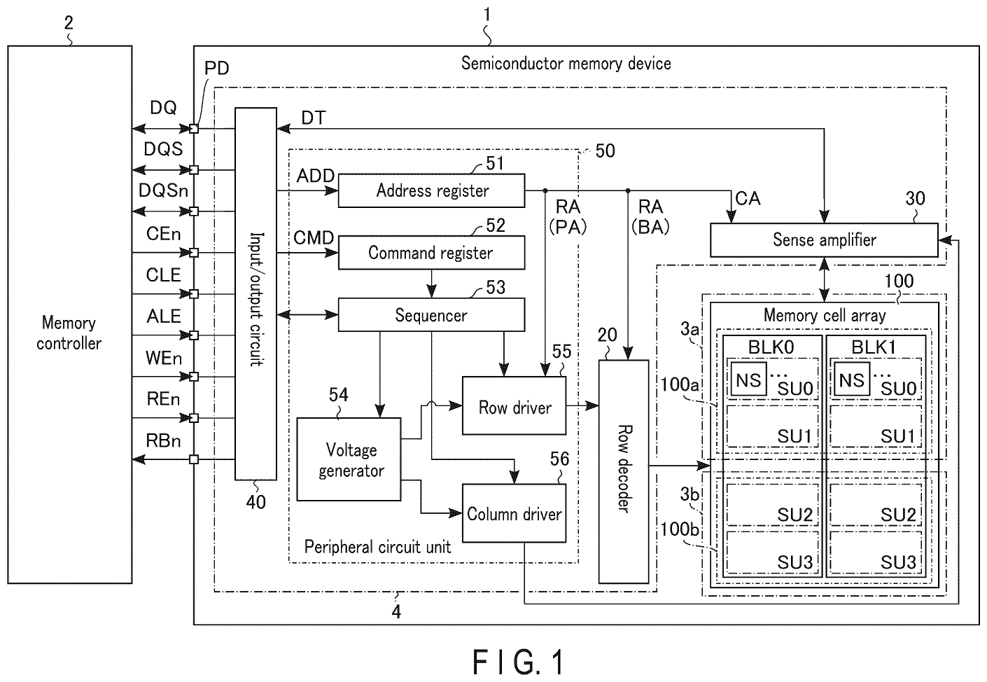

First, an example of an overall configuration of a semiconductor memory device 1 will be described with reference to FIG. 1. FIG. 1 is a block diagram illustrating an overall configuration of a memory system including the semiconductor memory device 1. In FIG. 1, a part of coupling between the components is indicated by arrow lines, but the coupling between the components is not limited thereto.

As illustrated in FIG. 1, the memory system includes the semiconductor memory device 1 and a memory controller 2.

The semiconductor memory device 1 is, for example, a three-dimensional stacked NAND flash memory. The three-dimensional stacked NAND flash memory includes a plurality of non-volatile memory cell transistors arranged three-dimensionally on a semiconductor substrate.

The memory controller 2 instructs the semiconductor memory device 1 to perform a read operation, a write operation, an erase operation, and the like based on a request from a host device (not illustrated). In addition, the memory controller 2 manages a memory space of the semiconductor memory device 1.

The semiconductor memory device 1 includes a plurality of external coupling terminals PD. The semiconductor memory device 1 is coupled to the memory controller 2 via the external coupling terminals PD. In addition, the semiconductor memory device 1 is supplied with a power supply voltage from the outside via the external coupling terminal PD.

The semiconductor memory device 1 is configured to be controllable by the memory controller 2. For example, the semiconductor memory device 1 transmits and receives a signal DQ and timing signals DQS and DOSn to and from the memory controller 2. The signal DQ is, for example, data DT, a memory address ADD, or a command CMD. The memory address ADD is information indicating a location of a memory cell transistor in a memory cell array 100. For example, the command CMD includes instructions for executing a read operation, a write operation, an erase operation, and the like. The timing signals DQS and DQSn are timing signals used at the time of input and output of the data DT. The timing signal DOSn is an inverted signal of the timing signal DQS.

In addition, the semiconductor memory device 1 receives various control signals from the memory controller 2. The control signals include, for example, a chip enable signal CEn, a command latch enable signal CLE, an address latch enable signal ALE, a write enable signal WEn, and a read enable signal REn.

The chip enable signal CEn is a signal for enabling the semiconductor memory device 1. The command latch enable signal CLE is a signal indicating that the signal DQ is a command. The address latch enable signal ALE is a signal indicating that the signal DQ is an address. The write enable signal WEn is a signal for fetching the signal DQ if the signal DQ is the command CMD or the memory address ADD. Every time the signal WEn is toggled, the command CMD or the memory address ADD is fetched into the semiconductor memory device 1. The read enable signal REn is a signal for the memory controller 2 to read data from the semiconductor memory device 1. For example, at the time of data output, the semiconductor memory device 1 generates the signals DQS and DOSn based on the signal REn.

The semiconductor memory device 1 transmits a ready/busy signal RBn to the memory controller 2. The ready/busy signal RBn is a signal indicating whether the semiconductor memory device 1 is in a state in which the semiconductor memory device 1 is not able to receive the command CMD from the memory controller 2 (busy state) or in a state in which the semiconductor memory device 1 is able to receive the command CMD from the memory controller 2 (ready state).

Next, an internal configuration of the semiconductor memory device 1 will be described.

The semiconductor memory device 1 includes a plurality of array chips 3 and a circuit chip 4. In the example illustrated in FIG. 1, the semiconductor memory device 1 includes two array chips 3a and 3b. Note that the number of the array chips 3 is not limited to two.

Each of the array chips 3 is a chip provided with an array of non-volatile memory cell transistors.

The circuit chip 4 is a chip provided with a circuit for controlling the array chips 3. For example, the semiconductor memory device 1 has a structure in which the plurality of array chips 3 and the circuit chip 4 are bonded together (hereinafter, also referred to as a “bonded structure”). Hereinafter, the array chips 3 and the circuit chip 4 are simply referred to as a “chip” in a case where a type of the chip is not limited.

The semiconductor memory device 1 includes the memory cell array 100. The memory cell array 100 is a region in which non-volatile memory cell transistors are three-dimensionally arranged. The memory cell array 100 is provided in the array chips 3a and 3b. Hereinafter, a part of the memory cell array 100 provided in the array chip 3a will be referred to as a “memory cell array 100a”. A part of the memory cell array 100 provided in the array chip 3b is referred to as a “memory cell array 100b”. That is, the memory cell array 100 includes the memory cell arrays 100a and 100b.

The memory cell array 100 includes a plurality of blocks BLK. In the example of FIG. 1, the memory cell array 100 includes two blocks BLK0 and BLK1. Each of the blocks BLK is, for example, a set of a plurality of memory cell transistors from which data is collectively erased. In the present embodiment, one block BLK is provided in a region where a part of the memory cell array 100a and a part of the memory cell array 100b are combined. That is, each of the block BLK includes a plurality of memory cell transistors provided in the memory cell array 100a and a plurality of memory cell transistors provided in the memory cell array 100b. Each of the plurality of memory cell transistors in the blocks BLK is associated with a row and a column.

Each of the blocks BLK includes a plurality of string units SU. Each of the string units SU constitutes, for example, a set of a plurality of NAND strings NS collectively selected in the write operation or the read operation. In the example of FIG. 1, each of the blocks BLK includes four string units SU0, SU1, SU2, and SU3. For example, the memory cell array 100a (array chip 3a) includes the string units SU0 and SU1 of each of the blocks BLK. The memory cell array 100b (array chip 3b) includes the string units SU2 and SU3 of each of the blocks. Note that an arrangement of the string units SU included in the array chips 3a and 3b is arbitrary.

Each of the string units SU includes a plurality of NAND strings NS. Each of the NAND strings NS includes a set of a plurality of memory cell transistors coupled in series.

Note that the number of blocks BLK in the memory cell array 100 and the number of string units SU in the block BLK are arbitrary. A circuit configuration of the memory cell array 100 will be described later.

Next, the circuit chip 4 will be described. The circuit chip 4 includes a row decoder 20, a sense amplifier 30, an input/output circuit 40, and a peripheral circuit unit 50.

The row decoder 20 is a decode circuit of a row address RA (block address BA). The row decoder 20 is coupled to the input/output circuit 40, an address register 51, a row driver 55, and the memory cell array 100. The row decoder 20 selects one of the blocks BLK in the memory cell array 100 based on a decoding result of the row address RA (block address BA). The row decoder 20 applies voltages to interconnects in a row direction of the selected block BLK (word lines and select gate lines to be described later).

The sense amplifier 30 is a circuit that writes and reads the data DT. The sense amplifier 30 is coupled to the input/output circuit 40, the address register 51, a column driver 56, and the memory cell array 100. The sense amplifier 30 reads the data DT from the memory cell array 100 during the read operation. In addition, the sense amplifier 30 supplies voltages based on write data DT to the memory cell array 100 during the write operation. The sense amplifier 30 can apply voltages to interconnects in a column direction (bit lines to be described later).

The input/output circuit 40 is a circuit that inputs and outputs the signal DQ and various control signals. The input/output circuit 40 is coupled to the memory controller 2 via the external coupling terminals PD. In addition, the input/output circuit 40 is coupled to the address register 51, a command register 52, a sequencer 53, and the sense amplifier 30.

In a case where the input signal DQ is the data DT (write data), the input/output circuit 40 receives the input signal DO based on the timing signals DQS and DQSn. Then, the input/output circuit 40 transmits the data DT to the sense amplifier 30. In addition, the input/output circuit 40 outputs the data DT (read data) to the memory controller 2 together with the timing signals DQS and DOSn.

In a case where the input signal DQ is the memory address ADD, the input/output circuit 40 transmits the memory address ADD to the address register 51. In addition, in a case where the input signal DQ is the command CMD, the input/output circuit 40 transmits the command CMD to the command register 52.

The input/output circuit 40 transmits various control signals received from the memory controller 2 to the sequencer 53.

The input/output circuit 40 transmits the ready/busy signal RBn received from the sequencer 53 to the memory controller 2.

The peripheral circuit unit 50 controls an operation in the memory cell array 100. The peripheral circuit unit 50 includes the address register 51, the command register 52, the sequencer 53, a voltage generator 54, the row driver 55, and the column driver 56.

The address register 51 is a register that temporarily stores the memory address ADD. The address register 51 is coupled to the input/output circuit 40, the row driver 55, the row decoder 20, and the sense amplifier 30. The address register 51 receives the memory address ADD from the input/output circuit 40. For example, the memory address ADD includes the row address RA and a column address CA. The row address RA is an address designating an interconnect in the row direction of the memory cell array 100. The column address CA is an address designating an interconnect in the column direction of the memory cell array 100. For example, the row address RA includes the block address BA and a page address PA. For example, the block address BA is used for selection between the blocks BLK. Hereinafter, one of the blocks BLK that has been selected is referred to as a “selected block BLK”. In addition, one of the blocks BLK that has not been selected is referred to as a “non-selected block BLK”. The page address PA is used for selection among the interconnects (word lines and select gate lines) in the row direction. The column address CA is used for selection among the interconnects (bit lines) in the column direction. For example, the address register 51 transmits the page address PA to the row driver 55. The address register 51 transmits the block address BA to the row decoder 20. The address register 51 transmits the column address CA to the sense amplifier 30.

The command register 52 is a register that temporarily stores the command CMD. The command register 52 is coupled to the input/output circuit 40 and the sequencer 53. The command register 52 transfers the command CMD to the sequencer 53.

The sequencer 53 is a circuit that controls the entire operation of the semiconductor memory device 1. The sequencer 53 may function as a controller of the semiconductor memory device 1. For example, the sequencer 53 is coupled to the input/output circuit 40, the voltage generator 54, the row driver 55, the column driver 56, the row decoder 20, and the sense amplifier 30. For example, the sequencer 53 controls the voltage generator 54, the row driver 55, the column driver 56, the row decoder 20, and the sense amplifier 30. For example, the sequencer 53 executes a write operation, a read operation, an erase operation, and the like based on the command CMD.

The voltage generator 54 generates voltages used for the write operation, the read operation, and the erase operation based on the control of the sequencer 53. The voltage generator 54 is coupled to the sequencer 53, the row driver 55, and the column driver 56. The voltage generator 54 supplies voltages to the row driver 55 and the column driver 56.

The row driver 55 is a driver that supplies voltages to the row decoder 20. The row driver 55 is coupled to the sequencer 53, the voltage generator 54, and the row decoder 20. For example, the row driver 55 supplies voltages to the row decoder 20 based on the row address RA (page address PA).

The column driver 56 is a driver that supplies voltages to the sense amplifier 30. The column driver 56 is coupled to the sequencer 53, the voltage generator 54, and the sense amplifier 30. For example, the column driver 56 supplies voltages to the sense amplifier 30.

### 1.1.2 Circuit Configuration of Memory Cell Array

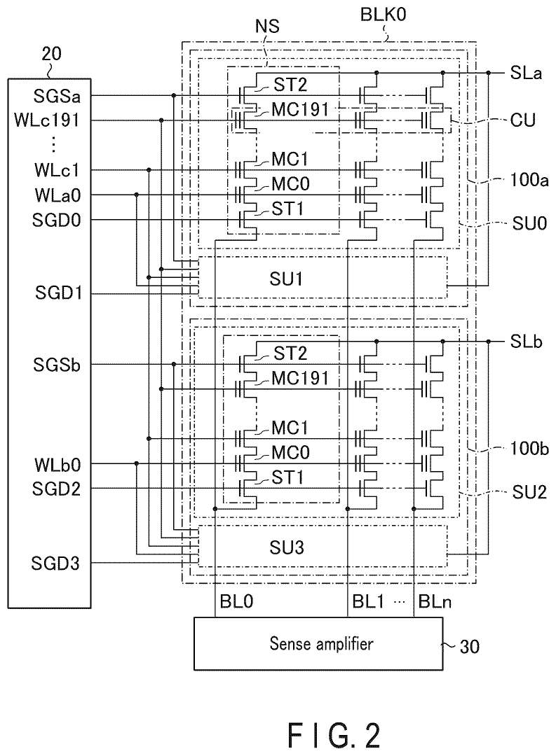

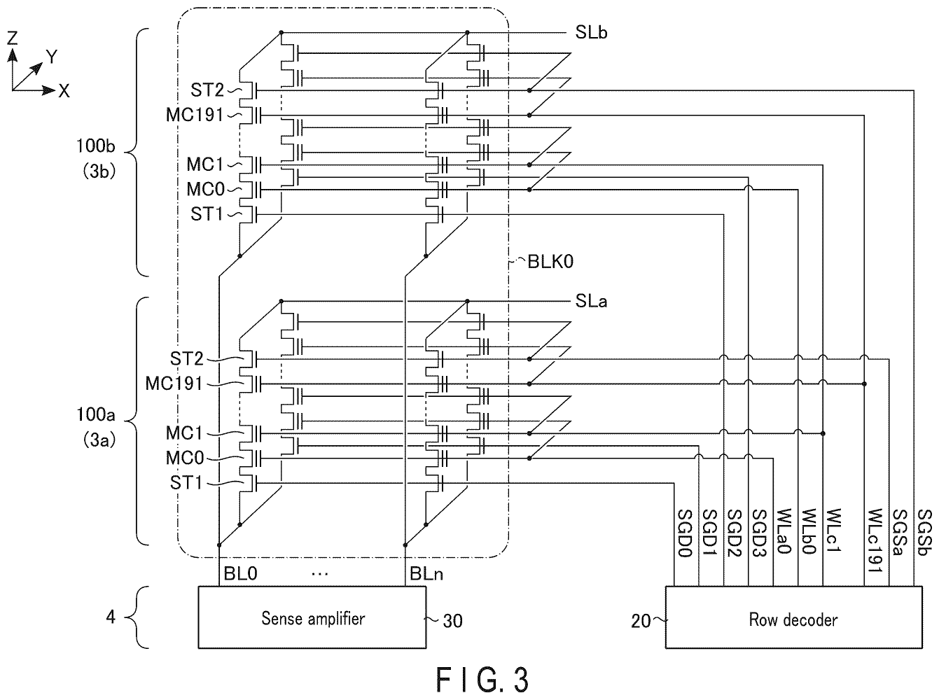

Next, an example of a circuit configuration of the memory cell array 100 will be described with reference to FIGS. 2 and 3. FIG. 2 is a plan view illustrating a circuit configuration of the memory cell array 100. FIG. 3 is a perspective view illustrating the circuit configuration of the memory cell array 100. Although the example of FIGS. 2 and 3 illustrates the circuit configuration of the block BLK0, the same applies to the other block BLK. Hereinafter, a direction in which word lines WL extend in the array chips 3 is referred to as an X direction. A direction which intersects with the X direction and in which bit lines BL extend is referred to as a Y direction. A direction intersecting the X direction and the Y direction and in which the array chips 3a and 3b and the circuit chip 4 are stacked is referred to as a Z direction.

As shown in FIG. 2, for example, the block BLK0 includes the four string units SU0 to SU3. More specifically, the memory cell array 100a includes the string units SU0 and SU1 of the block BLK0. The memory cell array 100b includes the string units SU2 and SU3 of the block BLK0.

Each of the string units SU includes the plurality of NAND strings NS.

Each of the NAND strings NS includes a plurality of memory cell transistors MC and selection transistors ST1 and ST2. In the example of FIG. 2, each NAND string NS includes 192 memory cell transistors MC0 to MC191. Note that the number of memory cell transistors MC included in the NAND string NS is arbitrary.

The memory cell transistors MC store data in a non-volatile manner. Each of the memory cell transistors MC includes a control gate and a charge storage layer. The memory cell transistors MC may be of a metal-oxide-nitride-oxide-silicon (MONOS) type or of a floating gate (FG) type. In the MONOS type, an insulating layer is used as the charge storage layer. In the FG type, a conductor is used as the charge storage layer. Hereinafter, a case where the memory cell transistors MC are of the MONOS type will be described.

The selection transistors ST1 and ST2 are used to select the string unit SU during various operations. Hereinafter, the string unit SU that has been selected is referred to as a “selected string unit SU”. In addition, the string unit SU that has not been selected is referred to as a “non-selected string unit SU”. The number of the selection transistors ST1 and ST2 is arbitrary. One or more selection transistors ST1 and ST2 may be included in each of the NAND strings NS.

Current paths of the memory cell transistors MC and the selection transistors ST1 and ST2 in each NAND string NS are coupled in series. In the example of FIG. 2, the current paths of the selection transistor ST1, the memory cell transistors MC0 to MC191, and the selection transistor ST2 are coupled in series in this order from a lower side to an upper side in the drawing. That is, the selection transistor ST1, the memory cell transistors MC0 to MC191, and the selection transistor ST2 are sequentially coupled from the bit lines BL to a source line SL. A drain of the selection transistor ST1 is coupled to one of the bit lines BL. A source of the selection transistor ST2 is coupled to the source line SL.

Control gates of the plurality of memory cell transistors MC0 to MC191 in the block BLK are commonly coupled to the word lines WL0 to WL191, respectively. In the present embodiment, each block BLK includes the word lines WL coupled to the memory cell transistors MC of the memory cell array 100a, the word lines WL coupled to the memory cell transistors MC of the memory cell array 100b, and the word lines WL commonly coupled to the memory cell transistors MC of the memory cell array 100a and the memory cell transistors MC of the memory cell array 100b. That is, the memory cell array 100a (array chip 3a) and the memory cell array 100b (array chip 3b) share some of the word lines WL.

Hereinafter, the word lines WL provided individually for each of the array chips 3 are referred to as “individual word lines WL”. In a case where word line WL coupled to the memory cell transistors MC of the memory cell array 100a (array chip 3a) and not coupled to the memory cell transistors MC of the memory cell array 100b (array chip 3b) are specified, it is referred to as “individual word line WLa”. In a case where word line WL coupled to the memory cell transistors MC of the memory cell array 100b (array chip 3b) and not coupled to the memory cell transistors MC of the memory cell array 100a (array chip 3a) are specified, these are referred to as “individual word line WLb”. In a case where word line WL commonly coupled to the memory cell transistors MC of the memory cell array 100a (array chip 3a) and the memory cell transistors MC of the memory cell array 100b (array chip 3b) are specified, these are referred to as “common word line WLc”. In other words, the individual word line WLa couple the array chip 3a and the row decoder 20. The individual word line WLb couple the array chip 3b and the row decoder 20. The common word line WLc couples the array chips 3a and 3b and the row decoder 20.

In the example of FIG. 2, the plurality of memory cell transistors MC0 of the string units SU0 and SU1 of the block BLK0 provided in the memory cell array 100a are commonly coupled to an individual word line WLa0. The plurality of memory cell transistors MC0 of the string units SU2 and SU3 of the block BLK0 provided in the memory cell array 100b are commonly coupled to an individual word line WLb0. The plurality of memory cell transistors MC1 of the string units SU0 to SU3 of the block BLK0 provided in the memory cell arrays 100a and 100b are commonly coupled to a common word line WLc1. Similarly, the other memory cell transistors MC are respectively coupled to the corresponding common word lines WLc. For example, the plurality of memory cell transistors MC191 of the string units SU0 to SU3 are commonly coupled to a common word line WLc191. In other words, the memory cell array 100a (array chip 3a) and the memory cell array 100b (array chip 3b) share the word lines WL1 to WL191 without sharing the word line WL0. That is, the memory cell transistors MC disposed on the source line SL side of the NAND string NS are coupled to the common word lines WLc, and the memory cell transistors MC disposed on the bit lines BL side are coupled to the individual word lines WL. Note that the number of common word lines WLc and an arrangement of the target common word lines WLc in each block BLK are arbitrary. In other words, the number and the arrangement of the individual word lines WLa and WLb in each block BLK are arbitrary.

In each block BLK, gates of the plurality of selection transistors ST1 in the string unit SU are commonly coupled to one select gate line SGD. In the example of FIG. 2, the gates of the plurality of selection transistors ST1 in the string unit SU0 are commonly coupled to a select gate line SGD0. Similarly, the gates of the plurality of selection transistors ST1 in the string unit SU1 are commonly coupled to a select gate line SGD1. The gates of the plurality of selection transistors ST1 in the string unit SU2 are commonly coupled to a select gate line SGD2. The gates of the plurality of selection transistors ST1 in the string unit SU3 are commonly coupled to a select gate line SGD3.

In each block BLK, gates of the plurality of selection transistors ST2 in the plurality of string units SU of the memory cell array 100a (array chip 3a) are commonly coupled to one select gate line SGS. Similarly, the gates of the plurality of selection transistors ST2 in the plurality of string units SU of the memory cell array 100b (array chip 3b) are commonly coupled to one select gate line SGS. Hereinafter, the select gate line SGS coupled to the selection transistors ST2 of the memory cell array 100a and not coupled to the selection transistors ST2 of the memory cell array 100b will be referred to as a “select gate line SGSa”. The select gate line SGS coupled to the selection transistors ST2 of the memory cell array 100b and not coupled to the selection transistors ST2 of the memory cell array 100a will be referred to as a “select gate line SGSb”. In the example of FIG. 2, the gates of the plurality of selection transistors ST2 in the string units SU0 and SU1 are commonly coupled to the select gate line SGDa. Similarly, the gates of the plurality of selection transistors ST2 in the string units SU2 and SU3 are commonly coupled to the select gate line SGDb. That is, the memory cell array 100a and the memory cell array 100b do not share the select gate lines SGS. The memory cell array 100a and the memory cell array 100b may share the select gate lines SGS. Alternatively, similarly to the select gate line SGD, the select gate line SGS may be provided for each string unit SU.

The individual word lines WLa and WLb, the common word line WLc, and the select gate lines SGD and SGS are coupled to the row decoder 20. The row decoder 20 can apply different voltages to the individual word line WLa and the individual word line WLb.

Drains of the plurality of selection transistors ST1 in the string unit SU are coupled to different bit lines BL. In other words, the bit lines BL are commonly coupled to one NAND string NS in each string unit SU of each block BLK. That is, the memory cell array 100a and the memory cell array 100b share the bit lines BL. The same column address CA is assigned to the plurality of NAND strings NS coupled to one bit line BL. In the example of FIG. 2, each string unit SU includes n+1 NAND strings NS (n is an integer of 0 or more). That is, the string unit SU includes n+1 selection transistors ST1. The drains of the n+1 selection transistors ST1 in the string unit SU are coupled to the n+1 bit lines BL0 to BLn, respectively. The bit lines BL0 to BLn are coupled to the sense amplifier 30, respectively.

The plurality of string units SU of the plurality of blocks BLK of the memory cell array 100a (array chip 3a) are commonly coupled to one source line SL. That is, the sources of the plurality of selection transistors ST2 in the memory cell array 100a are commonly coupled to one source line SL. Similarly, the plurality of string units SU of the plurality of blocks BLK of the memory cell array 100b (array chip 3b) are commonly coupled to one source line SL. That is, the sources of the plurality of selection transistors ST2 in the memory cell array 100b are commonly coupled to one source line SL. Hereinafter, in a case where the source line SL coupled to the selection transistors ST2 of the memory cell array 100a and not coupled to the selection transistors ST2 of the memory cell array 100b are specified, these are referred to as a “source line SLa”. In a case where the source line SL coupled to the selection transistors ST2 of the memory cell array 100b and not coupled to the selection transistors ST2 of the memory cell array 100a are specified, these are referred to as a “source line SLb”. The memory cell array 100a and the memory cell array 100b may share the source line SL.

Hereinafter, a set of the memory cell transistors MC coupled to one word line WL in one string unit SU is referred to as a “cell unit CU”. For example, in a case where a memory cell transistor MC stores one bit data, a storage capacity of the cell unit CU is defined as “one page data”. The cell unit CU may have a storage capacity of two page data or more based on the number of bits of data stored in the memory cell transistor MC.

As illustrated in FIG. 3, in the Z direction, an array region (the string units SU2 and SU3) of the block BLK0 of the memory cell array 100b is disposed above an array region (the string units SU0 and SU1) of the block BLK0 of the memory cell array 100a. That is, the NAND strings NS of the memory cell array 100a and the NAND strings NS of the memory cell array 100b arranged above the NAND strings NS of the memory cell array 100a are included in the same block BLK. In the example of FIG. 3, in one block BLK, the plurality of memory cell transistors MC arranged side by side in the X direction and the Y direction are commonly coupled to one word line WL. In each of the memory cell arrays 100a and 100b, the NAND strings NS arranged side by side in the Y direction are commonly coupled to the bit line BL. Further, the NAND strings NS of the memory cell array 100a and the NAND strings NS of the memory cell array 100b arranged side by side in the Z direction are commonly coupled to one bit line BL.

### 1.1.3 Circuit Configuration of Row Decoder

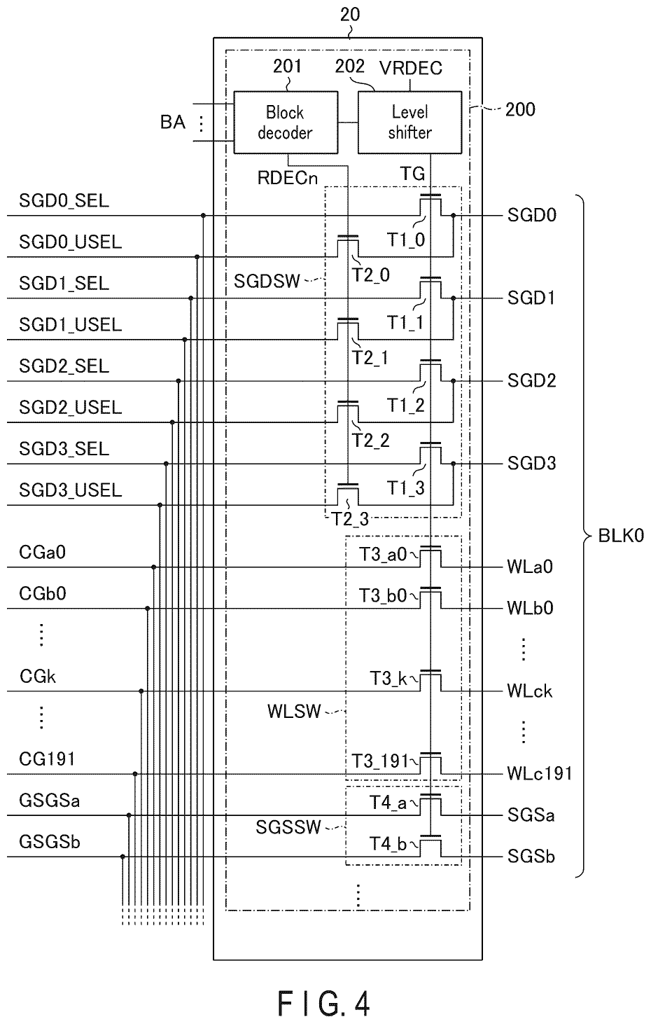

Next, a circuit configuration of the row decoder 20 will be described with reference to FIG. 4. FIG. 4 is a circuit diagram of the row decoder 20. In the following description, in a case where an end of a transistor is limited to neither of the source and the drain, one of the source and the drain of the transistor is referred to as “one end of the transistor”, and the other of the source and the drain of the transistor is referred to as “the other end of the transistor”.

As illustrated in FIG. 4, the row decoder 20 includes a plurality of row decoder units 200 provided for each of the blocks BLK. Although the example of FIG. 4 illustrates one of the row decoder units 200 corresponding to the block BLK0, the other one of the row decoder units 200 corresponding to the other block BLK has the same configuration.

The row decoder unit 200 includes a block decoder 201, a level shifter 202, a WL switch circuit group WLSW, an SGD switch circuit group SGDSW, and an SGS switch circuit group SGSSW.

The block decoder 201 decodes the block address BA. The block decoder 201 is coupled to the level shifter 202 and the SGD switch circuit group SGDSW. The block decoder 201 transmits a result (signal) obtained by decoding the block address BA to the level shifter 202 and the SGD switch circuit group SGDSW. The block decoder 201 is coupled to a plurality of switch circuits (transistors T2) of the SGD switch circuit group SGDSW via a signal line RDECn. The transistors T2 of the SGD switch circuit group SGDSW are controlled based on a voltage of the signal applied to the signal line RDECn. Note that the signal line RDECn may be coupled to the level shifter 202.

The level shifter 202 shifts a level of a potential of the signal received from the block decoder 201. For example, the level shifter 202 shifts a level of a voltage (potential) of a high (“H”) level signal received from the block decoder 201 to a voltage VRDEC. The level shifter 202 is coupled to a plurality of switch circuits (transistors T3) of the WL switch circuit group WLSW, a plurality of switch circuits (transistors T1) of the SGD switch circuit group SGDSW, and a plurality of switch circuits (transistors T4) of the SGS switch circuit group SGSSW via a signal line TG. The transistors T3 of the WL switch circuit group WLSW, the transistors T1 of the SGD switch circuit group SGDSW, and the transistors T4 of the SGS switch circuit group SGSSW are controlled based on a voltage of the signal applied to the signal line TG.

The SGD switch circuit group SGDSW is a set of a plurality of switch circuits for controlling coupling between the row driver 55 and the plurality of select gate lines SGD. The SGD switch circuit group SGDSW includes a plurality of high-withstand-voltage n-channel MOS transistors T1 and T2. The transistors T1 and T2 function as switch circuits for controlling coupling between the row driver 55 and the select gate line SGD, respectively. In the example of FIG. 4, the SGD switch circuit group SGDSW includes transistors T1_0 to T1_3 and T2_0 to T2_3. The number and the arrangement of the transistors T1 and T2 are designed based on the configuration of the select gate line SGD.

One end of the transistor T1_0 is coupled to the select gate line SGD0. The other end of the transistor T1_0 is coupled to the row driver 55 via an interconnect line SGD0_SEL. A gate of the transistor T1_0 is coupled to the signal line TG.

One end of the transistor T2_0 is coupled to the select gate line SGD0. The other end of the transistor T2_0 is coupled to the row driver 55 via an interconnect SGD0_USEL. A gate of the transistor T2_0 is coupled to the signal line RDECn.

One end of the transistor T1_1 is coupled to the select gate line SGD1. The other end of the transistor T1_1 is coupled to the row driver 55 via an interconnect SGD1_SEL. A gate of the transistor T1_1 is coupled to the signal line TG.

One end of the transistor T2_1 is coupled to the select gate line SGD1. The other end of the transistor T2_1 is coupled to the row driver 55 via the interconnect SGD1_USEL. A gate of the transistor T2_1 is coupled to the signal line RDECn.

One end of the transistor T1_2 is coupled to the select gate line SGD2. The other end of the transistor T1_2 is coupled to the row driver 55 via the interconnect SGD2_SEL. A gate of the transistor T1_2 is coupled to the signal line TG.

One end of the transistor T2_2 is coupled to the select gate line SGD2. The other end of the transistor T2_2 is coupled to the row driver 55 via the interconnect SGD2_USEL. A gate of the transistor T2_2 is coupled to the signal line RDECn.

One end of the transistor T1_3 is coupled to the select gate line SGD3. The other end of the transistor T1_3 is coupled to the row driver 55 via the interconnect SGD3_SEL. A gate of the transistor T1_3 is coupled to the signal line TG.

One end of the transistor T2_3 is coupled to the select gate line SGD3. The other end of the transistor T2_3 is coupled to the row driver 55 via the interconnect SGD3_USEL. A gate of the transistor T2_3 is coupled to the signal line RDECn.

The row driver 55 applies a voltage corresponding to the selected block BLK to the interconnects SGD0_SEL to SGD3_SEL. In addition, the row driver 55 applies a voltage corresponding to the non-selected block BLK to the interconnects SGD0_USEL to SGD3_USEL.

The WL switch circuit group WLSW is a set of a plurality of switch circuits for controlling coupling between the row driver 55 and the plurality of word lines WL. The WL switch circuit group WLSW includes a plurality of high-withstand-voltage n-channel MOS transistors T3. The transistors T3 function as switch circuits that control coupling between the row driver 55 and the word lines WL. In the example of FIG. 4, the WL switch circuit group WLSW includes transistors T3_a0, T3_b0, . . . , T3_k (k is an integer of 1 or more), . . . , T3_191. For example, the variable k indicates a boundary between the transistors T3 corresponding to the individual word lines WL and the transistors T3 corresponding to the common word lines WLc. For example, the transistors T3_a0 to T3_a(k−1) correspond to the individual word lines WLa0 to WLa(k−1), respectively. The transistors T3_b0 to T3_b(k−1) correspond to the individual word lines WLb0 to WLb(k−1), respectively. The transistors T3_k to T3_191 correspond to the common word lines WLck to WLc191, respectively. The number and the arrangement of the transistors T3 are designed based on the configuration of the word lines WL.

One end of the transistor T3_a0 is coupled to the individual word line WLa0. The other end of the transistor T3_a0 is coupled to the row driver 55 via the interconnect CGa0. A gate of the transistor T3_a0 is coupled to the signal line TG.

One end of the transistor T3_b0 is coupled to the individual word line WLb0. The other end of the transistor T3_b0 is coupled to the row driver 55 via the interconnect line CGb0. A gate of the transistor T3_b0 is coupled to the signal line TG. That is, the individual word line WLa0 and the individual word line WLb0 are coupled to different switch circuits (transistors T3).

One end of the transistor T3_k is coupled to the common word line WLck. The other end of the transistor T3_k is coupled to the row driver 55 via an interconnect CGk. A gate of the transistor T3_k is coupled to the signal line TG.

One end of the transistor T3_191 is coupled to the common word line WLc191. The other end of the transistor T3_191 is coupled to the row driver 55 via an interconnect CG191. A gate of the transistor T3_191 is coupled to the signal line TG.

The row driver 55 applies voltages corresponding to the selected block BLK to the interconnects CGa0, CGb0, and CG1 to CG191.

The SGS switch circuit group SGSSW is a set of a plurality of switch circuits for controlling coupling between the row driver 55 and the plurality of select gate lines SGS. The SGS switch circuit group SGSSW includes a plurality of high-withstand-voltage n-channel MOS transistors T4. The transistors T4 function as switch circuits that control coupling between the row driver 55 and the select gate lines SGS. In the example of FIG. 4, the SGS switch circuit group SGSSW includes two high-withstand-voltage n-channel MOS transistors T4_a and T4_b. The number and the arrangement of the transistors T4 are designed based on the configuration of the select gate line SGS.

One end of the transistor T4_a is coupled to the select gate line SGSa. The other end of the transistor T4_a is coupled to the row driver 55 via the interconnect GSGSa. A gate of the transistor T4_a is coupled to the signal line TG.

One end of the transistor T4_b is coupled to the select gate line SGSb. The other end of the transistor T4_b is coupled to the row driver 55 via the interconnect GSGSb. A gate of the transistor T4_b is coupled to the signal line TG.

The row driver 55 applies voltages corresponding to the selected block BLK to the interconnects GSGSa and GSGSb.

For example, in the write operation, the read operation, or the erase operation, in a case where the block address BA matches the corresponding block BLK0, the block decoder 201 transmits an “H” level signal to the level shifter 202, and applies a low (“L”) level voltage (for example, the ground voltage Vss) to the signal line RDECn. As a result, the level shifter 202 applies the voltage VRDEC to the signal line TG as a voltage at the “H” level. In addition, in a case where the block address BA does not match the corresponding block BLK0, the block decoder 201 transmits an “L” level signal to the level shifter 202 and applies an “H” level voltage to the signal line RDECn. As a result, the level shifter 202 applies a voltage at the “L” level to the signal line TG. In a case where the voltage at the “H” level is applied to the signal line TG, the transistors T1, T3, and T4 are turned on. In addition, in a case where the voltage at the “H” level is applied to the signal line RDECn, the transistors T2 are turned on. The voltage at the “H” level applied to the signal line RDECn is lower than the voltage at the “H” level (voltage VRDEC) applied to the signal line TG.

### 1.1.4 Arrangement of Chips

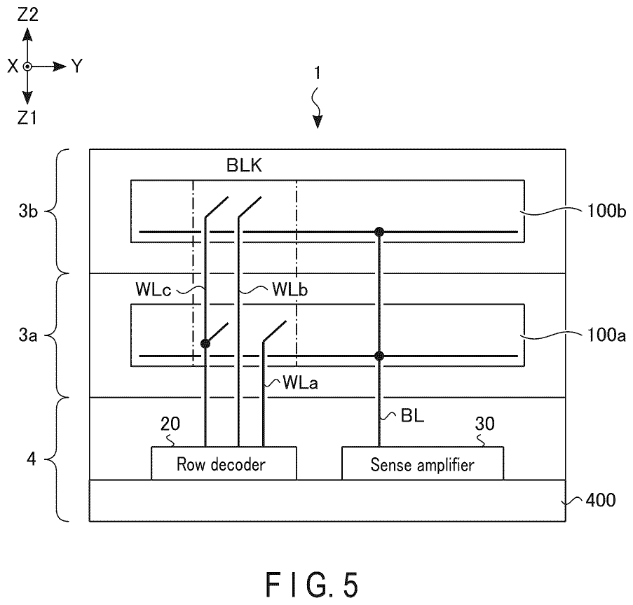

Next, an example of the arrangement of the chips will be described with reference to FIG. 5. FIG. 5 is a cross-sectional view illustrating the arrangement of the array chips 3a and 3b and the circuit chip 4. In the example of FIG. 5, one individual word line WLa, one individual word line WLb, one common word line WLc, and one bit line BL are illustrated in order to simplify the illustration. The select gate lines SGD and SGS and the source lines SL are omitted.

Hereinafter, in a case where the Z direction is specified, a direction from the array chip 3 toward the circuit chip 4 is referred to as a Z1 direction, and a direction facing the Z1 direction is referred to as a Z2 direction.

As illustrated in FIG. 5, the array chip 3a is bonded onto the circuit chip 4 in the Z2 direction. Then, the array chip 3b is bonded onto the array chip 3a. In other words, the circuit chip 4 is bonded to a surface of the array chip 3a facing the Z1 direction. Then, the array chip 3b is bonded to a surface of the array chip 3a facing the Z2 direction. That is, the circuit chip 4, the array chip 3a, and the array chip 3b are sequentially stacked in the Z2 direction.

The row decoder 20 and the sense amplifier 30 are provided on the semiconductor substrate 400 of the circuit chip 4.

The array chips 3a and 3b are respectively provided with the memory cell arrays 100a and 100b.

A part of the memory cell array 100a and a part of the memory cell array 100b arranged side by side in the Z direction constitute the block BLK. The common word line WLc is shared between the memory cell array 100a and the memory cell array 100b. The individual word lines WLa are coupled to the memory cell transistors MC of the memory cell array 100a and is not coupled to the memory cell transistors MC of the memory cell array 100b. The individual word lines WLb are coupled to the memory cell transistors MC of the memory cell array 100b and is not coupled to the memory cell transistor MC of the memory cell array 100a.

The bit lines BL are shared by the memory cell array 100a and the memory cell array 100b.

### 1.1.5 Arrangement of Memory Cell Arrays

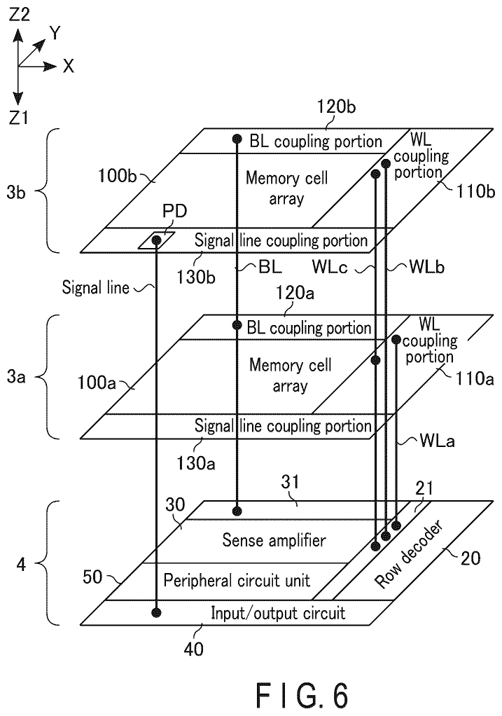

Next, an example of the arrangement of the memory cell array 100 will be described with reference to FIG. 6. FIG. 6 is a perspective view illustrating the arrangement of the array chips 3a and 3b and the circuit chip 4. In the example of FIG. 6, one individual word line WLa, one individual word line WLb, one common word line WLc, one bit line BL, and one signal line (for example, a signal line that transfers the signal DQ) are illustrated in order to simplify the illustration. The select gate lines SGD and SGD and the source lines SL are omitted.

As illustrated in FIG. 6, the array chip 3a includes the memory cell array 100a, a WL coupling portion 110a, a BL coupling portion 120a, and a signal coupling portion 130a. Similarly, the array chip 3b includes the memory cell array 100b, a WL coupling portion 110b, a BL coupling portion 120b, and a signal coupling portion 130b.

The WL coupling portions 110a and 110b are regions where contact plugs, interconnects, and the like for coupling the word lines WL and the select gate lines SGD and SGS to the row decoder 20 are provided.

In the example of FIG. 6, the WL coupling portion 110a is arranged adjacent to the memory cell array 100a in the X direction. The word lines WL provided in the memory cell array 100a are drawn to the WL coupling portion 110a. In the WL coupling portion 110a, each of the word lines WL provided in the memory cell array 100a is coupled to a contact plug electrically coupled to the row decoder 20. Note that the arrangement of the WL coupling portion 110a is arbitrary. For example, a plurality of WL coupling portions 110a may be provided. The WL coupling portion 110a may also be provided in the memory cell array 100a.

Similarly, the WL coupling portion 110b is arranged adjacent to the memory cell array 100b in the X direction. Further, the WL coupling portion 110b is disposed above the WL coupling portion 110a. The word lines WL provided in the memory cell array 100b are drawn to the WL coupling portion 110b. In the WL coupling portion 110b, each of the word lines WL provided in the memory cell array 100b is coupled to a contact plug electrically coupled to the row decoder 20. Note that the arrangement of the WL coupling portion 110b is arbitrary. For example, a plurality of WL coupling portions 110b may be provided. The WL coupling portion 110b may also be provided in the memory cell array 100b.

For example, the individual word line WLa is coupled to the row decoder 20 via the WL coupling portion 110a.

For example, the individual word line WLb is coupled to the row decoder 20 via the WL coupling portions 110a and 110b. In the WL coupling portion 110a, the individual word line WLb is not electrically coupled to the word line WL provided in the memory cell array 100a.

For example, the common word line WLc is coupled to the row decoder 20 via the WL coupling portions 110a and 110b. The word line WL of the memory cell array 100a and the word line WL of the memory cell array 100b are electrically coupled in the WL coupling portion 110a.

The BL coupling portions 120a and 120b are regions where contact plugs, interconnects, and the like for coupling the bit lines BL and the sense amplifier 30 are provided.

In the example of FIG. 6, the BL coupling portion 120a is arranged adjacent to the memory cell array 100a in the Y direction. The bit line BL provided in the memory cell array 100a is drawn to the BL coupling portion 120a. In the BL coupling portion 120a, the bit line BL provided in the memory cell array 100a is coupled to a contact plug electrically coupled to the sense amplifier 30. The arrangement of the BL coupling portion 120a is arbitrary. For example, a plurality of the BL coupling portions 120a may be provided.

Similarly, the BL coupling portion 120b is arranged adjacent to the memory cell array 100b in the Y direction. Further, the BL coupling portion 120b is disposed above the BL coupling portion 120a. The bit line BL provided in the memory cell array 100b is drawn to the BL coupling portion 120b. In the BL coupling portion 120b, the bit line BL provided in the memory cell array 100b is coupled to a contact plug electrically coupled to the sense amplifier 30. The arrangement of the BL coupling portion 120b is arbitrary. For example, a plurality of the BL coupling portions 120b may be provided.

The bit lines BL are coupled to the sense amplifier 30 via the BL coupling portions 120a and 120b. The bit lines BL of the memory cell array 100a and the bit lines BL of the memory cell array 100b are electrically coupled in the BL coupling portion 120a.

The signal coupling portions 130a and 130b are regions where signal lines (contact plugs, interconnects, and the like) for coupling the external coupling terminals PD and the input/output circuit 40 are provided. In the example of FIG. 6, the signal coupling portion 130a is provided at an end of the array chip 3a in the Y direction. Similarly, the signal coupling portion 130b is provided at an end of the array chip 3b in the Y direction. For example, the input/output circuit 40 and the signal coupling portions 130a and 130b are arranged along the Z direction. Note that the arrangement of the signal coupling portions 130a and 130b is arbitrary. For example, a plurality of the signal coupling portions 130a and 130b may be respectively provided.

The signal coupling portion 130b is provided with the external coupling terminals PD. For example, the external coupling terminals PD is coupled to the input/output circuit 40 via signal lines provided in the signal coupling portions 130a and 130b. The signal lines are not electrically coupled to the memory cell arrays 100a and 100b.

The circuit chip 4 includes, for example, a WL hook-up portion 21 and a BL hook-up portion 31.

The WL hook-up portion 21 is a region in which a contact plugs, interconnects, and the like for coupling the row decoder 20 to the word line WL and the select gate lines SGD and SGS are provided. In the circuit chip 4, the word line WL and the select gate lines SGD and SGS are coupled to the row decoder 20 via the WL hook-up portion 21. The WL hook-up portion 21 and the WL coupling portions 110a and 110b are disposed along the Z direction. The row decoder 20 is disposed adjacent to the WL hook-up portion 21. For example, the WL switch circuit group WLSW, the SGD switch circuit group SGDSW, and the SGS switch circuit group SGSSW of the row decoder 20 described with reference to FIG. 4 may be arranged in the WL hook-up portion 21.

The BL hook-up portion 31 is a region where a contact plug, interconnect, and the like for coupling the sense amplifier 30 and the bit line BL are provided. In the circuit chip 4, the bit line BL is coupled to the sense amplifier 30 via the BL hook-up portion 31. The BL hook-up portion 31 and the BL coupling portions 120a and 120b are disposed along the Z direction. In addition, the sense amplifier 30 is disposed adjacent to the BL hook-up portion 31.

### 1.1.6 Cross-Sectional Configuration of Memory Cell Array

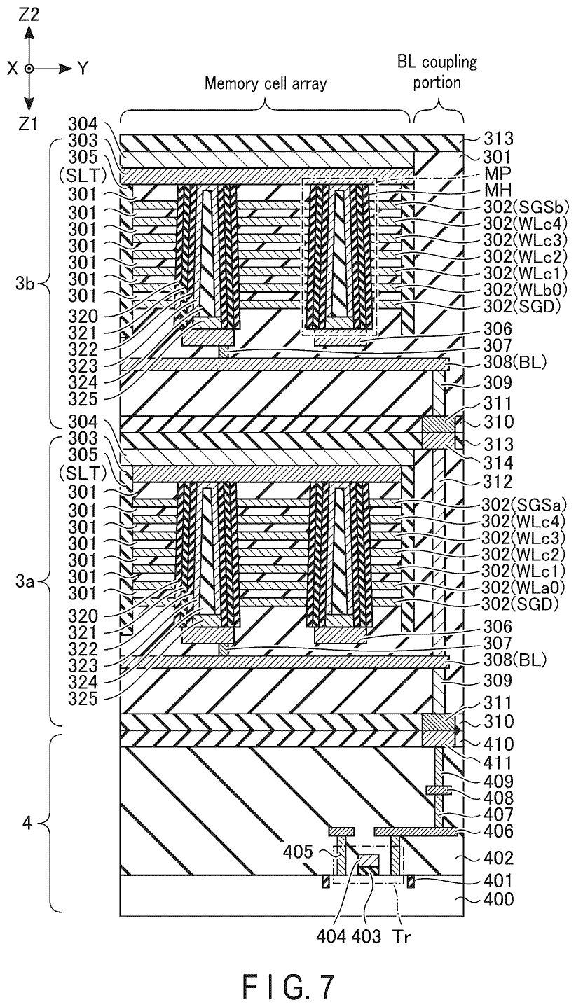

Next, an example of a cross-sectional configuration of the memory cell array 100 will be described with reference to FIG. 7. FIG. 7 is a cross-sectional view of the memory cell array 100. In the example of FIG. 7, a case where five word lines WL0 to WL4 are provided in each array chip 3 will be described. More specifically, in the example of FIG. 7, the array chip 3a includes the individual word line WLa0 and the common word lines WLc1 to WLc4. The array chip 3b includes the individual word line WLb0 and the common word lines WLc1 to WLc4.

As illustrated in FIG. 7, the semiconductor memory device 1 has a bonded structure in which the array chips 3a and 3b and the circuit chip 4 are bonded. The chips are electrically coupled to each other via electrodes provided on the chips.

First, an internal configuration of the array chip 3a will be described.

The array chip 3a includes the memory cell array 100a and various interconnect layers for coupling to other chips.

The array chip 3a includes insulating layers 301, 305, 310, and 313, interconnect layers 302, 304, and 308, a semiconductor layer 303, and conductors 306, 307, 309, 311, 312, and 314.

In the memory cell array 100a, a plurality of the insulating layers 301 and a plurality of the interconnect layers 302 are alternately stacked one by one. In the example of FIG. 7, seven interconnect layers 302 functioning as the select gate line SGD, the word lines WL0a0 and WLc1 to WLc4, and the select gate line SGS are sequentially stacked in the Z2 direction.

The insulating layers 301 may contain, for example, silicon oxide (SiO). The interconnect layers 302 include a conductive material. The conductive material may contain a metal material, an n-type semiconductor, or a p-type semiconductor. As the conductive material of the interconnect layers 302, for example, a stacked structure of titanium nitride (TiN) and tungsten (W) is used. In this case, TiN is provided so as to cover W. Note that the interconnect layers 302 may contain a high dielectric constant material such as aluminum oxide (AlO). In this case, the high dielectric constant material is provided so as to cover the conductive material.

For example, the plurality of interconnect layers 302 are separated for each block BLK by a member SLT extending in the X direction. The member SLT includes the insulating layer 305. The insulating layer 305 may contain SiO. Note that the member SLT may include a conductor electrically coupled to the semiconductor layer 303 and not electrically coupled to the interconnect layers 302. In this case, the insulating layer 305 is provided so as to surround a side surface of the member SLT. Then, an interior of the insulating layer 305 is filled with the conductor.

In the Z2 direction, the semiconductor layer 303 is provided above the interconnect layer 302 functioning as the select gate line SGS. The insulating layer 301 is provided between the interconnect layer 302 and the semiconductor layer 303. The semiconductor layer 303 functions as the source line SL. In the Z2 direction, the interconnect layer 304 is provided on the semiconductor layer 303. The interconnect layer 304 is used as an interconnect layer for electrically coupling the semiconductor layer 303 to other chips. The interconnect layer 304 includes a conductive material. The conductive material may contain a metal material, an n-type semiconductor, or a p-type semiconductor. For example, the interconnect layer 304 contains aluminum (Al).

The memory cell array 100a is provided with a plurality of memory pillars MP. For example, the memory pillars MP have a substantially columnar shape extending in the Z direction. One memory pillar MP corresponds to one NAND string NS. The memory pillar MP penetrates (passes) the plurality of interconnect layers 302. An end of the memory pillar MP in the Z2 direction is in contact with the semiconductor layer 303.

In the Z1 direction, the conductor 306 is provided on an end of the memory pillar MP. For example, the conductor 306 has a substantially columnar shape. The conductor 306 functions as a contact plug. A conductor 307 is provided on the conductor 306. For example, the conductor 307 has a substantially columnar shape. The conductor 307 functions as a contact plug. In the Z1 direction, a plurality of interconnect layers 308 are provided above the memory pillar MP. The interconnect layers 308 extend in the Y direction. The plurality of interconnect layers 308 are arranged side by side in the X direction. The interconnect layers 308 function as the bit lines BL. The interconnect layers 308 are electrically coupled to one of the memory pillars MP via the conductors 306 and 307. That is, one end of the memory pillar MP is coupled to the source line SL. The other end of the memory pillar MP is coupled to the bit lines BL. The conductors 306 and 307 and the interconnect layers 308 may contain a metal material such as W, Al, or copper (Cu).

In the Z1 direction, a conductor 309 is provided on the interconnect layer 308. In other words, in the BL coupling portion 120a, the interconnect layer 308 (bit line BL) is coupled to the conductor 309. For example, the conductor 309 has a substantially columnar shape. The conductor 309 functions as a contact plug. The conductor 309 may contain a metal material such as W, Al, or Cu.

In the Z1 direction, an insulating layer 310 is provided on the insulating layer 301. The insulating layer 310 may contain SiO.

A plurality of conductors 311 are provided in the same layer as the insulating layer 310. The conductors 311 function as an electrode for electrical coupling with another chip. The conductors 311 may contain Cu.

In the Z1 direction, the conductors 311 are provided on the conductor 309.

Note that a plurality of interconnect layers may be provided between the conductors 311 and the interconnect layers 308.

In the Z2 direction, a conductor 312 is provided on the interconnect layer 308. In other words, in the BL coupling portion 120a, the interconnect layer 308 (bit line BL) is coupled to the conductor 312. For example, the conductor 312 has a substantially columnar shape. The conductor 312 functions as a contact plug. The conductor 312 may contain a metal material such as W, Al, or Cu.

In the Z2 direction, an insulating layer 313 is provided on the interconnect layer 304 and the insulating layer 301. The insulating layer 313 may contain SiO.

A plurality of conductors 314 are provided in the same layer as the insulating layer 313. The conductors 314 function as an electrode for electrical coupling with another chip. The conductors 314 may contain Cu.

In the Z2 direction, the conductor 314 is provided on the conductor 312.

Next, an internal configuration of the memory pillar MP will be described.

The memory pillar MP includes a block insulating film 320, a charge storage layer 321, a tunnel insulating film 322, a semiconductor layer 323, a core layer 324, and a cap layer 325.

More specifically, memory holes MH penetrating (passing through) the plurality of interconnect layers 302 are provided. The memory hole MH corresponds to the memory pillar MP. An end of the memory hole MH in the Z2 direction reaches the semiconductor layer 303. On a side surface of the memory hole MH, the block insulating film 320, the charge storage layer 321, and the tunnel insulating film 322 are laminated in this order from the outside. For example, in a case where the memory hole MH has a cylindrical shape, the block insulating film 320, the charge storage layer 321, and the tunnel insulating film 322 have a cylindrical shape. The semiconductor layer 323 is provided so as to be in contact with a side surface of the tunnel insulating film 322. An end of the semiconductor layer 323 in the Z2 direction is in contact with the semiconductor layer 303. The semiconductor layer 323 is a region in which the channels of the memory cell transistors MC and the selection transistors ST1 and ST2 are provided. Therefore, the semiconductor layer 323 functions as a signal line that couples current paths of the selection transistor ST2, the memory cell transistors MC0 to MC4, and the selection transistor ST1. Inside of the semiconductor layer 323 is filled with the core layer 324. The cap layer 325 whose side surface is in contact with the tunnel insulating film 322 is provided on the end portion of the semiconductor layer 323 and the core layer 324 in the Z1 direction. That is, the memory pillar MP includes the semiconductor layer 323 that passes through the interiors of the plurality of interconnect layers 302 and extends in the Z direction.

The block insulating film 320, the tunnel insulating film 322, and the core layer 324 may contain SiO. The charge storage layer 321 may contain silicon nitride (SiN). The semiconductor layer 323 and the cap layer 325 may contain, for example, polysilicon.

The memory cell transistor MC is configured by combining the memory pillar MP and the interconnect layer 302 functioning as the word line WL. In the example of FIG. 7, in the array chip 3a, the memory cell transistors MC0 to MC5 are configured by respectively combining the memory pillars MP and the interconnect layers 302 functioning as the word lines WL0a0 and WLc1 to WLc4. Similarly, in the array chip 3b, the memory cell transistors MC0 to MC5 are configured by respectively combining the memory pillars MP and the interconnect layers 302 functioning as the word lines WL0b0 and WLc1 to WLc4. In addition, the selection transistor ST1 is configured by combining the memory pillar MP and the interconnect layer 302 functioning as the select gate line SGD. The selection transistor ST2 is configured by combining the memory pillar MP and the interconnect layer 302 functioning as the select gate line SGS. In other words, the memory pillars MP include the memory cell transistors MC and the selection transistors ST1 and ST2.

Next, an internal configuration of the array chip 3b will be described. Hereinafter, differences from the array chip 3a will be mainly described.

In the array chip 3b, the conductors 312 and 314 described in the configuration of the array chip 3a are omitted. Other configurations are the same as those of the array chip 3a. In the example of FIG. 7, seven interconnect layers 302 functioning as the select gate line SGD, the word lines WL0b0 and WLc1 to WLc4, and the select gate line SGS are sequentially stacked in the Z2 direction. The interconnect layer 308 of the array chip 3b is electrically coupled to the interconnect layer 308 of the array chip 3a via the conductors 309 and 311 of the array chip 3b and the conductors 312 and 314 of the array chip 3a.

Next, the circuit chip 4 will be described.

The circuit chip 4 includes a plurality of transistors Tr and various interconnect layers. The plurality of transistors Tr are used for the row decoder 20, the sense amplifier 30, and the like.

More specifically, the circuit chip 4 includes a semiconductor substrate 400, insulating layers 401, 402, and 410, a gate insulating film 403, a gate electrode 404, conductors 405, 407, 409, and 411, and interconnect layers 406 and 408.

Isolation regions are provided in the vicinity of a surface of the semiconductor substrate 400. The isolation regions electrically isolate the n-type well region and the p-type well region provided in the vicinity of the surface of the semiconductor substrate 400, for example. The isolation regions are filled with the insulating layers 401. The insulating layers 401 may contain SiO.

The insulating layer 402 is provided on the semiconductor substrate 400. The insulating layer 402 may contain SiO.

Each of the transistors Tr includes the gate insulating film 403 provided on the semiconductor substrate 400, the gate electrode 404 provided on the gate insulating film 403, and a source and a drain (not illustrated) provided in the semiconductor substrate 400. The source and the drain are electrically coupled to the interconnect layer 406 via the conductor 405. The conductor 405 extends in the Z2 direction. The conductor 405 functions as a contact plug. The conductor 407 is provided on the interconnect layer 406. The conductor 407 extends in the Z2 direction. The conductor 407 functions as a contact plug. The interconnect layer 408 is provided on the conductor 407. The conductor 409 is provided on the interconnect layer 408. The conductor 409 extends in the Z2 direction. The conductor 409 functions as a contact plug. The interconnect layers 406 and 408 are configured by a conductive material. The conductors 405, 407, and 409, and the interconnect layers 406 and 408 may contain a metal material, a p-type semiconductor, or an n-type semiconductor. Note that the number of layers of the interconnect layers provided in the circuit chip 4 is arbitrary.

In the Z2 direction, an insulating layer 410 is provided on the insulating layer 402. The insulating layer 410 may contain SiO.

The plurality of conductors 411 are provided in the same layer as the insulating layer 410. The conductors 411 function as an electrode for electrical coupling with another chip. For example, one conductor 409 is provided on one conductor 411. The conductor 411 may contain a metal material such as Cu. The conductor 411 of the circuit chip 4 is in contact with (electrically coupled to) the conductors 311 of the array chip 3a.

### 1.2 Erase Operation

Next, the erase operation will be described. The erase operation of the present embodiment includes a block erase operation and a sub-block erase operation. In the block erase operation, one block BLK is selected and the erase operation is executed to this block. In the sub-block erase operation, one sub-block SB in the block BLK is selected and the erase operation is executed to this sub-block. The block BLK can be divided into a plurality of sub-blocks SB in which a plurality of word lines WL are taken as one unit.

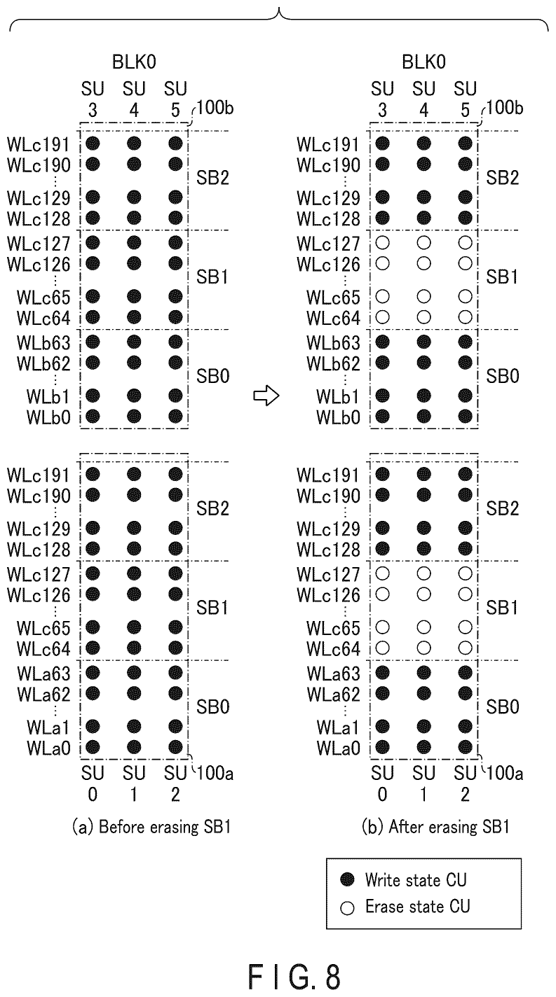

Next, a specific example of the sub-block erase operation will be described with reference to FIG. 8. FIG. 8 is a diagram illustrating a configuration of the block BLK and a change in a write state of data by the sub-block erase operation. The example of FIG. 8 illustrates the sub-block erase operation of the sub-block SB1. The same applies to the other sub-blocks SB.

As shown in FIG. 8, one circle indicates one cell unit CU. A black circle indicates a state in which data is written in the cell unit CU (a state in which valid data is stored). A white circle indicates a state in which data in the cell unit CU has been erased (a state in which valid data is not stored).

In the example of FIG. 8, the block BLK0 includes six string units SU0 to SU5. The string units SU0 to SU2 are provided in the memory cell array 100a. The string units SU3 to SU5 are provided in the memory cell array 100b. Each of the memory cell arrays 100a and 100b is provided with 192 word lines WL0 to WL191.

More specifically, the string units SU0 to SU2 of the memory cell array 100a are coupled to the individual word lines WLa0 to WLa63 and the common word lines WLc64 to WLc191. The string units SU3 to SU5 of the memory cell array 100b are coupled to the individual word lines WLb0 to WLb63 and the common word lines WLc64 to WLc191. That is, the memory cell arrays 100a and 100b share the word lines WL64 to WL191 without sharing the word lines WL0 to WL63.

For example, a set of the cell units CU of the string units SU0 to SU2 of the memory cell array 100a coupled to the individual word lines WLa0 to WLa63 and the cell units CU of the string units SU3 to SU5 of the memory cell array 100b coupled to the individual word lines WLb0 to WLb63 are set as a sub-block SB0. A set of the cell units CU of the string units SU0 to SU2 of the memory cell array 100a and the cell units CU of the string units SU3 to SU5 of the memory cell array 100b coupled to the common word lines WLc64 to WLc127 is set as a sub-block SB1. A set of the cell units CU of the string units SU0 to SU2 of the memory cell array 100a and the cell units CU of the string units SU3 to SU5 of the memory cell array 100b coupled to the common word lines WLc128 to WLc191 is set as a sub-block SB2.

FIG. 8 (a) illustrates a state in which data is written in all the cell units CU in the block BLK0. In this state, for example, the sub-block erase operation of the sub-block SB1 is executed. Then, as illustrated in FIG. 8 (b), data in the cell units CU in the sub-block SB1 of the memory cell arrays 100a and 100b is erased.

### 1.3 Write Operation

Next, the write operation will be described. The write operation includes a program operation and a program verify operation.

The program operation is an operation of increasing a threshold voltage of the memory cell transistor MC by injecting electrons into the charge storage layer (alternatively, the threshold voltage is maintained by hardly injecting electrons into the charge storage layer). Hereinafter, a memory cell transistor MC for increasing the threshold voltage is referred to as a “program-target memory cell transistor MC”. The memory cell transistor MC that does not raise the threshold voltage is referred to as a “program-inhibited memory cell transistor MC”. In the program operation, each memory cell transistor MC is set to be program target or program inhibited based on the write data stored in the sense amplifier 30. For example, in a case where the write data is “0”, the memory cell transistor MC is set as a program target. In a case where the write data is “1”, the memory cell transistor MC is set as program-inhibited.

The program verify operation is an operation of reading data and determining whether or not the threshold voltage of the memory cell transistor MC has reached a target level as a target (write target state) after the program operation. Hereinafter, a case where the number of the memory cell transistors MC in which the threshold voltage reaches the target level is greater than or equal to a preset number is referred to as “verification passed”, and a case where the number of the memory cell transistors MC in which the threshold voltage reaches the target level is less than the preset number is referred to as “verification failed”. More specifically, for example, in the program verify operation, in a case where the number of fail bits of the read data is less than a preset reference value, it is determined to be “verification passed”. On the other hand, in a case where the number of fail bits of the read data is greater than or equal to the preset reference value, it is determined to be “verification failed”. As a result of the program verify operation, the memory cell transistor MC that has not reached the threshold voltage of the write target state is set to the program-target memory cell transistor MC. In addition, the memory cell transistor MC that has reached the threshold voltage of the write target state is set to the program-inhibited memory cell transistor MC.

By repeating a combination of the program operation and the program verify operation (hereinafter, referred to as a “program loop”), the threshold voltage of the memory cell transistor MC is increased to the target level.

### 1.3.1 Command Sequence of Write Operation

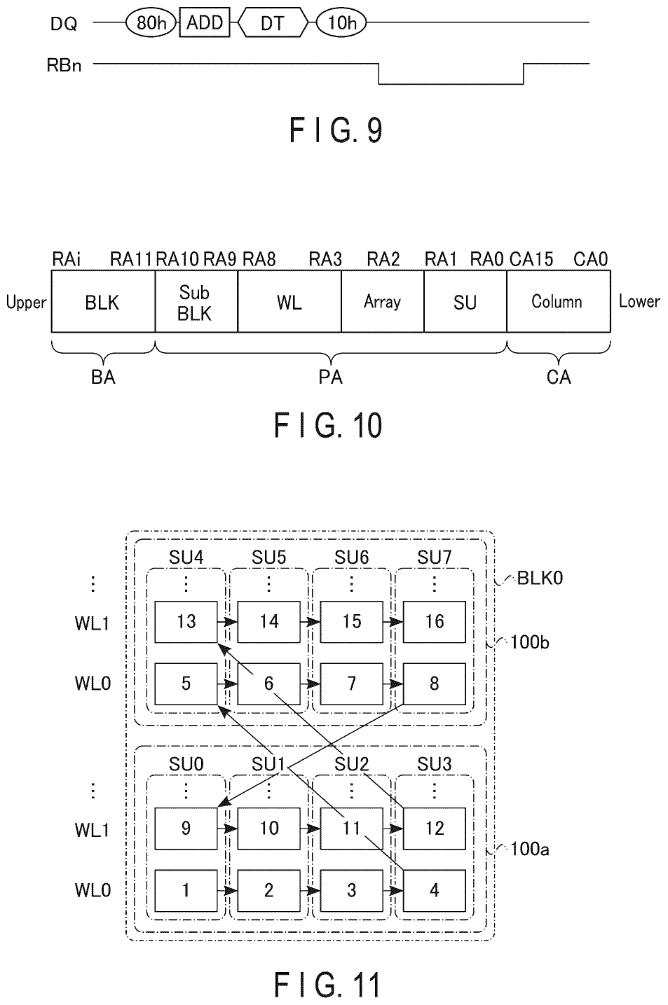

Next, an example of a command sequence of the write operation will be described with reference to FIG. 9. FIG. 9 is a command sequence of the write operation. In the example of FIG. 9, in order to simplify the description, the signals CEn, CLE, ALE, WEn, the signal REn, and the like other than the signal DQ and the signal RBn are omitted. Hereinafter, in the signal DQ, the command is indicated by a rounded frame, the memory address is indicated by a square frame, and the data is indicated by a hexagonal frame.

As illustrated in FIG. 9, the memory controller 2 first transmits a command “80h” to the semiconductor memory device 1. The command “80h” is a command notifying that the write operation will be performed.

Next, the memory controller 2 transmits the memory address ADD, the data DT, and a command “10h” to the semiconductor memory device 1. The command “10h” is a command instructing execution of the write operation. The memory address ADD can be transmitted in a plurality of cycles based on the configuration of the memory cell array 100.

Upon reception of the command “10h”, the sequencer 53 sets the ready/busy signal RBn to the “L” level and executes the write operation.

Upon completion of the write operation, the sequencer 53 sets the ready/busy signal RBn to the “H” level.

### 1.3.2 Memory Address

Next, an example of the memory address ADD will be described with reference to FIG. 10. FIG. 10 is a configuration diagram of the memory address ADD.

As illustrated in FIG. 10, the memory address ADD includes the block address BA, the page address PA, and the column address CA. In the example of FIG. 10, the column address CA is set to a lower address side, and the block address BA is set to an upper address side.

The column address CA is, for example, an area indicated by a 16 bit binary number from an address CAO to an address CA15. For example, the number of bits of the column address CA is arbitrarily set based on the number of bit lines BL (data length of one page data).

The page address PA is, for example, a region indicated by a 11 bit binary number from an address RA0 to an address RA10. The number of bits of the page address PA is arbitrarily set, for example, based on the configuration of the block BLK.

The block address BA is, for example, a region indicated by an address RA11 to an address RAi (i is an integer greater than 11). The number of bits of the block address BA is arbitrarily set, for example, based on the number of blocks BLK.

Next, details of the configuration of the page address PA will be described.

In the example of FIG. 10, the page address PA includes a string unit address, an array address, a word line address, and a sub-block address from the lower address side. For example, an order of selection of the cell units CU in the write operation or the read operation is based on the order of the addresses of the page addresses PA.

The string unit address is address information used for selecting the string units SU, that is, the select gate lines SGD. For example, in a case where one array chip 3 includes four string unit SU, the string unit address is indicated by the address RA0 and the address RA1 of two bits. Note that the number of bits of the string unit address is arbitrarily set based on, for example, the number of string units SU included in one array chip 3.

The array address is address information used for selecting the array chip 3. For example, in a case where the semiconductor memory device 1 includes two array chips 3a and 3b, that is, in a case where the memory cell array 100 includes the memory cell arrays 100a and 100b, the array address is indicated by the address RA2 of one bit. The number of bits of the array address is arbitrarily set based on the number of the array chips 3, for example.

The word line address is address information used for selecting the word line WL in the sub-block SB. In a case where the sub-block SB includes 64 word lines WL, the word line addresses are indicated by the addresses RA3 to RA8 of six bits. The number of bits of the word line address is arbitrarily set based on, for example, the number of word lines WL included in the sub-block SB.

The sub-block address is address information used for selecting the sub-block SB in the block BLK. In a case where the block BLK includes three or four sub-blocks SB, the sub-block address is indicated by the addresses RA9 and RA10 of two bits. The number of bits of the sub-block address is arbitrarily set based on, for example, the number of sub-blocks SB included in the block BLK.

### 1.3.3 Writing Order of Data

Next, an example of the writing order of data will be described with reference to FIG. 11. FIG. 11 is a diagram illustrating a writing order of data based on the memory address ADD illustrated in FIG. 10. The example of FIG. 11 schematically illustrates a cross-sectional configuration of the string unit SU in the block BLK0. One square in each string unit SU represents one cell unit CU corresponding to one word line WL. That is, one square corresponds to one write operation. The numbers in the squares in FIG. 11 indicate the writing order (selection order) of data in the cell units CU.

As shown in FIG. 11, for example, the block BLK0 includes eight string units SU0 to SU7. The string units SU0 to SU3 are provided in the memory cell array 100a. The string units SU4 to SU7 are provided in the memory cell array 100b.

For example, first, in a state where the word line WL0 and the array chip 3a (memory cell array 100a) are selected, the string unit address of the lower address is incremented. That is, the string units SU0 to SU3 of the memory cell array 100a are sequentially selected (write order “1” to “4”). Next, the array address of the upper address is incremented, and the array chip 3b (memory cell array 100b) is selected. In this state, the string unit address of the lower address is incremented. That is, the string units SU4 to SU7 of the memory cell array 100b are sequentially selected (write order “5” to “8”). Next, the word line address located above the array address is incremented. As a result, the word line WL1 is selected. As in the case of the word line WL0, the string units SU0 to SU3 (write order “9” to “12”) of the memory cell array 100a and the string units SU4 to SU7 (write order “13” to “16”) of the memory cell array 100b are sequentially selected. Thereafter, the word line WL and the string unit SU are similarly selected.

### 1.3.4 Specific Example in which Selected Cell Unit is Coupled to Common Word Line

Next, a specific example in which the selected cell unit CU (hereinafter, referred to as a “selected cell unit CU”) is coupled to the common word line WLc in the write operation will be described.

### 1.3.4.1 Configuration of Block and Write State of Data

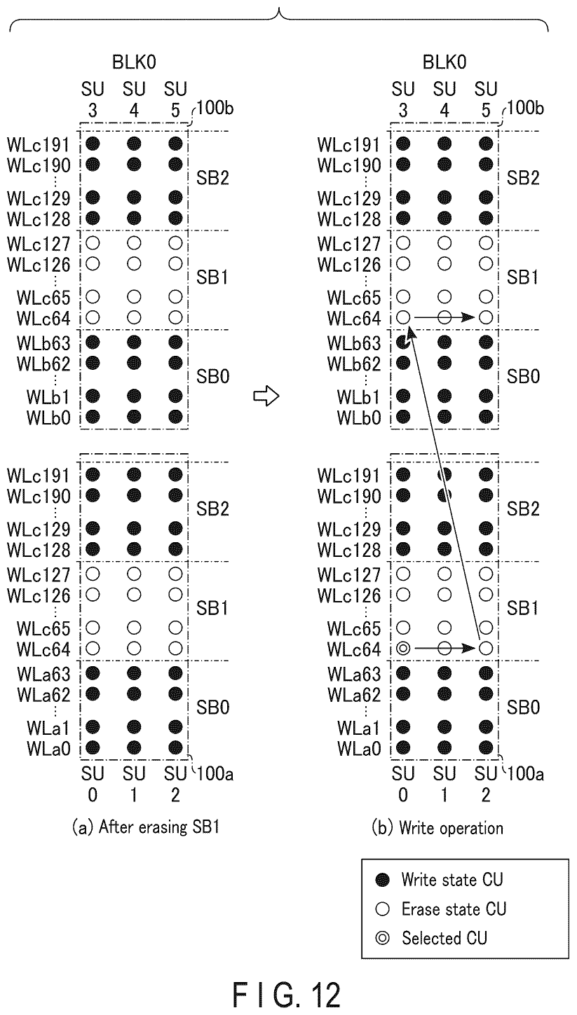

First, the configuration of the block BLK and the write state of data will be described with reference to FIG. 12. FIG. 12 is a diagram illustrating a configuration of the block BLK and a change in a write state of data by the write operation of the sub-block SB1.

As shown in FIG. 12, one circle indicates one cell unit CU. A black circle indicates a state in which data is written in the cell unit CU (a state in which valid data is stored). A white circle indicates a state in which data in the cell unit CU has been erased (a state in which valid data is not stored). A double circle indicates the selected cell unit CU.

The configuration of the block BLK0 is similar to that described in FIG. 8. The sub-block SB0 does not share the word line WL. The sub-blocks SB1 and SB2 share the word line WL.

More specifically, the string units SU0 to SU2 of the memory cell array 100a are coupled to the individual word lines WLa0 to WLa63 and the common word lines WLc64 to WLc191. The cell units CU corresponding to the individual word lines WLa0 to WLa63 are included in the sub-block SB0. The cell units CU corresponding to the common word lines WLc64 to WLc127 are included in the sub-block SB1. The cell units CU corresponding to the common word lines WLc128 to WLc191 are included in the sub-block SB2.

The string units SU3 to SU5 of the memory cell array 100b are coupled to the individual word lines WLb0 to WLb63 and the common word lines WLc64 to WLc191. The cell units CU corresponding to the individual word lines WLb0 to WLb63 are included in the sub-block SB0. The cell units CU corresponding to the common word lines WLc64 to WLc127 are included in the sub-block SB1. The cell units CU corresponding to the common word lines WLc128 to WLc191 are included in the sub-block SB2.

FIG. 12(a) illustrates a state in which the data of the sub-block SB1 is erased by the sub-block erase operation. For example, in this state, the write operation of the sub-block SB1 is executed. Then, as illustrated in FIG. 12(b), data is sequentially written from the cell unit CU of the string unit SU0 of the memory cell array 100a coupled to the common word line WLc64. In the case of the write operation of the sub-block SB1, the cell unit CU in the data writing state is on the bit line BL side and the source line SL side of the selected cell unit CU.

### 1.3.4.2 Voltage of Each Interconnect in Write Operation

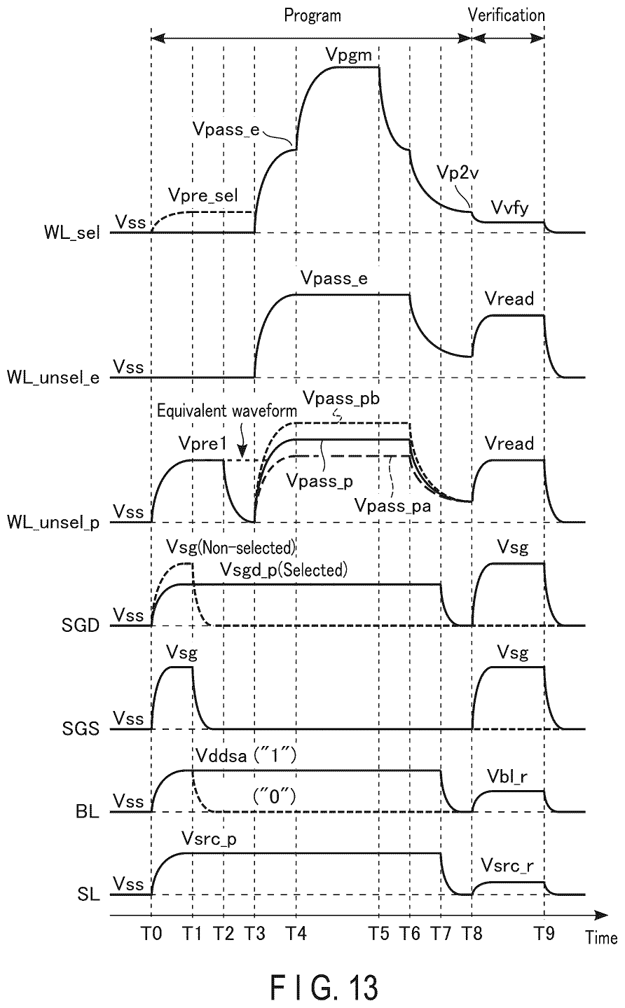

Next, a voltage of each interconnect in the write operation will be described with reference to FIG. 13. FIG. 13 is a timing chart illustrating a voltage of each interconnect in the write operation of the sub-block SB1. The example of FIG. 13 illustrates one program loop. In the following description, the word line WL selected as a target of the write operation is referred to as a “selected word line WL_sel”. In a case where the word line WL from which data has been erased is specified among the word lines WL that are not selected as the target of the write operation (hereinafter, referred to as a “non-selected word line WL”), the word line WL will be denoted as an “non-selected word line WL_unsel_e”. In a case where the word line WL in which data has been written is specified among the non-selected word lines WL, the word line WL will be denoted as a “non-selected word line WL_unsel_p”. In the example of FIG. 12 (b), the common word line WLc64 of the sub-block SB1 is selected. In this case, the common word line WLc64 is the selected word line WL_sel. The common word lines WLc65 to WLc127 are the non-selected word lines WL_unsel_e. The individual word lines WLa0 to WLa63, WLb0 to WLb63, and WLc128 to WLc191 are the non-selected word lines WL_unsel_p.

As illustrated in FIG. 13, first, a program operation at times T0 to T8 will be described.

In the program operation, a period from the time T0 to the time T3 is a precharge period of the channel of the selected memory cell transistor MC (hereinafter, referred to as a “selected memory cell transistor MC”).

At the time T0, precharge for inhibiting writing is performed on the channel of each NAND string NS in the selected block BLK. More specifically, the sense amplifier 30 applies a voltage Vddsa to the bit lines BL. The voltage Vddsa is a positive voltage higher than the voltage Vss. A voltage Vsrc_p is applied to the source lines SL (source lines SLa and SLb). The voltage Vsrc_p is a voltage for the purpose of precharging of the channel and improving cutoff characteristics of the selection transistor ST2. The voltage Vsrc_p is a positive voltage higher than the voltage Vss. Note that the voltage Vsrc_p may have the same voltage value as the voltage Vddsa. The row decoder 20 applies a voltage Vsgd_p to the select gate line SGD corresponding to the selected string unit SU. The voltage Vsgd_p is higher than the threshold voltage of the selection transistor ST1. The selection transistor ST1 is turned on. As a result, a voltage of the bit line BL equal to or higher than the voltage Vss is applied to the channel of the NAND string NS in the selected string unit SU. The row decoder 20 applies a voltage Vsg to the select gate line SGS and the select gate line SGD corresponding to the non-selected string unit SU. The voltage Vsg is higher than the voltage Vddsa. As a result, a higher voltage can be applied from the bit line BL or the source line SL to the channel of the NAND string NS in the non-selected string unit SU in a range of the voltage applied to the bit line BL or the source line SL. In addition, the row decoder 20 applies a voltage Vprel to the non-selected word line WL_unsel_p. The voltage Vprel is higher than the threshold voltage of the memory cell transistor MC that has been written. As a result, the memory cell transistor MC to which data has been written is turned on. The row decoder 20 applies the voltage Vss to the non-selected word line WL_unsel_e. The threshold voltage of the memory cell transistor MC from which data has been erased is lower than the voltage Vss. Therefore, the threshold voltage of the memory cell transistor MC from which data has been erased is turned on. The row decoder 20 applies the voltage Vss to the selected word line WL_sel. The selected memory cell transistor MC is turned on because the data has been erased. The row decoder 20 may apply a voltage Vpre_sel to the selected word line WL_sel. The voltage Vpre_sel is higher than the voltage Vss. By these operations, precharge is performed from the bit line BL or the source line SL to the channel of each NAND string NS in the selected block BLK.

At the time T1, the row decoder 20 applies the voltage Vss to the select gate line SGS and the select gate line SGD that is corresponding to the non-selected string unit SU. The selection transistor ST2 and the selection transistor ST1 that is corresponding to the non-selected string unit SU are turned off. As a result, the channel of each NAND string NS in the non-selected string unit SU is in a floating state.

In this state, the sense amplifier 30 applies the voltage Vss to the bit line BL corresponding to “0” data, that is, the bit line BL corresponding to the program-target selected memory cell transistor MC. As a result, the voltage Vss is applied to the channel corresponding to the program-target selected memory cell transistor MC in the selected string unit SU (the channel is discharged). On the other hand, the sense amplifier 30 continues to apply the voltage Vddsa to the bit line BL corresponding to “1” data, that is, the bit line BL corresponding to the program-inhibited selected memory cell transistor MC. Therefore, the selection transistor ST1 corresponding to the program-inhibited selected memory cell transistor MC is turned off. As a result, the channel corresponding to the program-inhibited selected memory cell transistor MC in the selected string unit SU is in a floating state. That is, each channel in the non-selected string unit SU and a channel corresponding to the program-inhibited selected memory cell transistor MC in the selected string unit SU are in a floating state.

At the time T2, the row decoder 20 applies the voltage Vss to the non-selected word line WL_unsel_p.

The times T3 to T7 are periods during which a write pulse is applied.

At the time T3, the row decoder 20 applies a voltage Vpass_e to the selected word line WL_sel and the non-selected word line WL_unsel_e. The row decoder 20 applies a voltage Vpass-pa to the individual word line WLa among the non-selected word lines WL_unsel_p. The row decoder 20 applies a voltage Vpass-pb to the individual word line WLb among the non-selected word lines WL_unsel_p. The row decoder 20 applies the voltage Vpass-p to the common word line WLc among the non-selected word lines WL_unsel_p. The voltage Vpass_e is a voltage applied to the memory cell transistor MC in the erase state. The voltage Vpass_e is a voltage that can be set regardless of the threshold voltage of the memory cell transistor MC in the write state. The voltages Vpass_p, Vpass_pa, and Vpass_pb are voltages applied to the memory cell transistor MC in the write state. The voltages Vpass_p, Vpass_pa, and Vpass_pb are voltages that turn the memory cell transistor MC on regardless of the threshold voltage of the memory cell transistor MC. Further, the voltages Vpass_p, Vpass_pa, and Vpass_pb are higher than the voltage Vprel. For example, in a case where the cell unit CU of the memory cell array 100a (array chip 3a) is selected, the voltages Vpass_p, Vpass_pa, and Vpass_pb have a relationship of Vpass_pa<Vpass_p<Vpass_pb. In addition, for example, in a case where the cell unit CU of the memory cell array 100b (array chip 3b) is selected, the voltages Vpass_p, Vpass_pa, and Vpass_pb have a relationship of Vpass_pa>Vpass_p>Vpass_pb. Note that the voltages Vpass_e, Vpass_p, Vpass_pa, and Vpass_pb may be different for each word line WL.

Each channel in the non-selected string unit SU and a channel corresponding to the program-inhibited selected memory cell transistor MC in the selected string unit SU are in a floating state. In a case where the potential of the word line WL rises, the potentials of these channels rise due to coupling (hereinafter, referred to as “channel boost”). Due to the channel boost, a potential difference between the word line WL and the channel is limited to a range in which writing does not occur.

At this time, in the array chip 3 (hereinafter, referred to as a “non-selected array chip 3”) not including the selected cell unit CU, all the string units SU are brought into a non-selected state. That is, the channel of each NAND string NS in the non-selected array chip 3 is in a floating state. In this state, the voltage of the individual word line WL corresponding to the non-selected word line WL_unsel_p on the non-selected array chip 3 side (for example, the voltage Vpass_pb) is set higher than the voltage Vpass_p of the other non-selected word lines WL_unsel_p. Then, the potential difference between the word line WL on the non-selected array chip 3 side and the channel is further reduced. As a result, an influence of write disturbance on the non-selected array chip 3 side is reduced. That is, the shift of the threshold voltage of the memory cell transistor MC not to be programmed is suppressed.

In addition, in the selected array chip 3, in order to suppress the shift of the threshold voltage of the memory cell transistor MC coupled to the non-selected word line WL, the voltage of the individual word line WL corresponding to the non-selected word line WL_unsel_p (for example, the voltage Vpass_pa) is set lower than the voltage Vpass_p of the other non-selected word lines WL_unsel_p. The voltage Vss is applied to a channel corresponding to the program-target selected memory cell transistor MC. Therefore, a potential difference between the word line WL on the selected array chip 3 side and the channel is further reduced. As a result, the influence of the write disturbance on the selected array chip 3 side is reduced.

Here, a voltage waveform applied to the non-selected word line WL_unsel_p can be considered as a waveform equivalent to a dotted line shown in FIG. 13 in the period from the time T2 to the time T4. At the time T2, the row decoder 20 may continuously apply the voltage Vprel without applying the voltage Vss to the non-selected word line WL_unsel_p. In the waveform in a solid line of the non-selected word line WL_unsel_p, the voltage Vss is applied to the non-selected word line WL_unsel_p (the voltage Vprel is discharged) at the time T2. Therefore, the potential of the precharged channel decreases during the period from the time T2 to the time T3. As the potential applied to the non-selected word line WL_unsel_p rises to the voltage Vprel in the period from the time T3 to the time T4, the potential of the channel recovers to the precharge potential in the period from the time T1 to the time T2. Thereafter, the potential of the channel is boosted by a difference between the voltage Vpass_p and the voltage Vprel. In this case, the potential of the channel corresponding to the non-selected word line WL_unsel_p can be lower than the potential of the channel corresponding to the non-selected word line WL_unsel_e.

At the time T4, the row decoder 20 applies a voltage Vpgm to the selected word line WL_sel. The voltage Vpgm is a high voltage for injecting electrons into the charge storage layer of the program-target selected memory cell transistor MC. The voltage Vpgm is a voltage higher than the voltages Vpass_e, Vpass_p, Vpass_pa, and Vpass_pb. As a result, in the program-target selected memory cell transistor MC, the potential difference (Vpgm-Vss) between the selected word line WL_sel and the channel increases. As a result, electrons are injected into the charge storage layer, and the threshold voltage of the selected memory cell transistor MC is increased. On the other hand, in the program-inhibited selected memory cell transistor MC, the potential difference between the selected word line WL_sel and the channel is smaller than that in the program-target memory cell transistor MC due to the channel boost. As a result, electrons are hardly injected into the charge storage layer, and the threshold voltage of the memory cell transistor MC is maintained (the threshold voltage does not fluctuate to the extent that the write target state transitions to a higher distribution).

At the time T5, the row decoder 20 applies a voltage Vpass-e to the selected word line WL_sel. That is, the voltage Vpgm is discharged.

During a period from the time T6 to the time T8, the row decoder 20 discharges the voltages applied to the selected word line WL_sel, the non-selected word line WL_unsel_e, and the non-selected word line WL_unsel_p. For example, the potentials of the selected word line WL_sel, the non-selected word line WL_unsel_e, and the non-selected word line WL_unsel_p decrease to a voltage Vp2v. The voltage Vp2v is higher than the voltage Vss.

At the time T7, the row decoder 20 applies the voltage Vss to the select gate lines SGD and SGS. In addition, the voltage Vss is applied to the source line SL. As a result, the program operation ends.

Next, the program verify operation at times T8 to T9 will be described.

At the time T8, the row decoder 20 applies a voltage Vvfy to the selected word line WL_sel. The voltage Vvfy is a verify voltage. The voltage Vvfy is based on the target level of the write operation (write target state). The sequencer 53 determines whether verification has been passed or failed based on a comparison result between the threshold voltage of the memory cell transistor MC and the voltage Vvfy. The row decoder 20 applies a voltage Vread to the non-selected word line WL_unsel_e and the non-selected word line WL_unsel_p. The voltage Vread is higher than the voltage Vvfy and is a voltage that turns the memory cell transistor MC on regardless of the threshold voltage of the memory cell transistor MC. As a result, the non-selected memory cell transistor MC is turned on. The row decoder 20 applies the voltage Vsg to the select gate line SGS and the select gate line SGD corresponding to the selected string unit SU. The row decoder 20 applies the voltage Vss to the select gate line SGD corresponding to the non-selected string unit SU. As a result, in the selected string unit SU, the selection transistor ST1 is turned on. In the non-selected string unit SU, the selection transistor ST1 is turned off. Note that the row decoder 20 may apply the voltage Vss after temporarily applying a voltage higher than the voltage Vss to the select gate line SGD corresponding to the non-selected string unit SU immediately after the time T8. As a result, the selection transistor ST1 is temporarily turned on. By temporarily turning on the selection transistor ST1 of the non-selected string unit SU, the channel of the NAND string NS of the non-selected string unit SU is discharged.

The sense amplifier 30 applies a voltage Vbl_r to the bit line. The voltage Vbl_r is a positive voltage higher than the voltage Vss. A voltage Vsrc_r is applied to the source line SL. The voltage Vsrc_r is higher than the voltage Vss and lower than the voltage Vbl_r. During a period from the time T8 to the time T9, the sense amplifier 30 reads data of the selected memory cell transistor MC.

At the time T9, the row decoder 20 applies the voltage Vss to the selected word line WL_sel, the non-selected word line WL_unsel_e, the non-selected word line WL_unsel_p, and the select gate lines SGD and SGS. The sense amplifier 30 applies the voltage Vss to the bit line BL. The voltage Vss is applied to the source line SL. As a result, the program verify operation ends.

### 1.3.5 Specific Example in which Selected Cell Unit is Coupled to Individual Word Line

Next, a specific example in which the selected cell unit CU is coupled to the individual word line WL in the write operation will be described. Hereinafter, a description will be given focusing on differences from the case where the selected cell unit CU is coupled to the common word line WLC.

### 1.3.5.1 Configuration of Block and Write State of Data

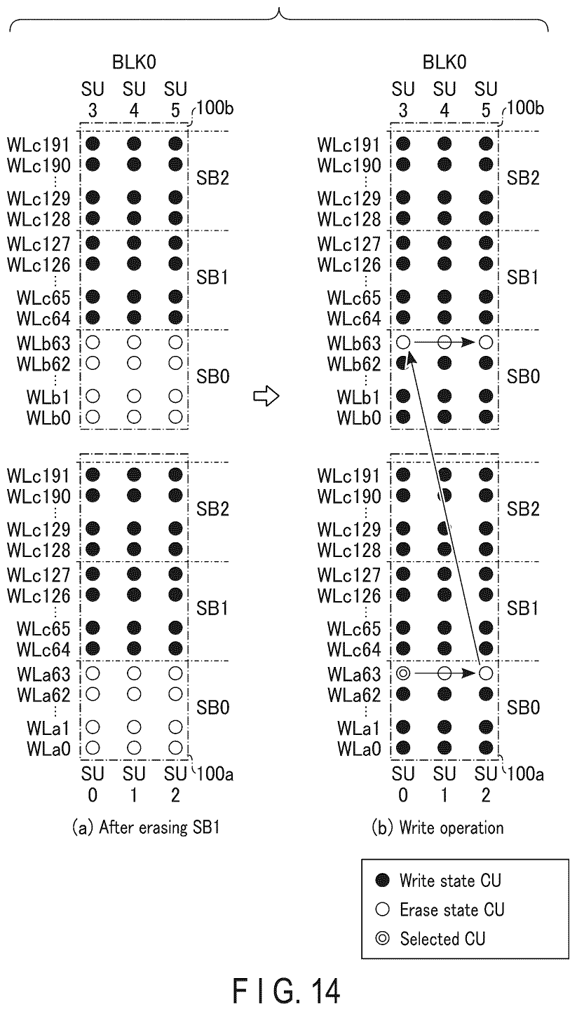

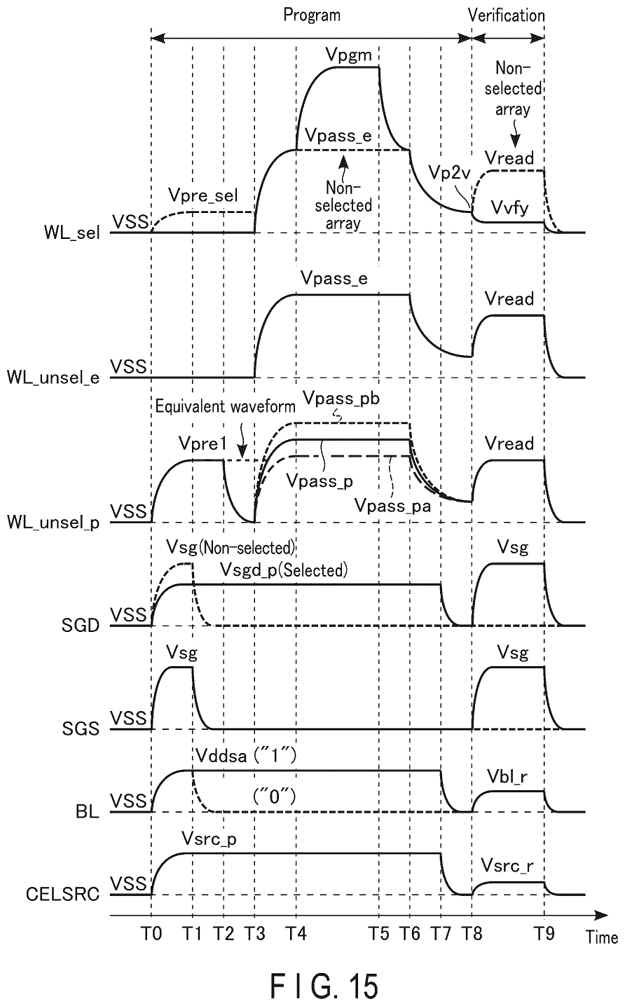

First, the configuration of the block BLK and the write state of data will be described with reference to FIG. 14. FIG. 14 is a diagram illustrating a configuration of the block BLK and a change in a write state of data by the write operation of the sub-block SB0.

As illustrated in FIG. 14, the configuration of the block BLK0 is similar to that in FIG. 12.

FIG. 14 (a) illustrates a state in which the data of the sub-block SB0 is erased by the sub-block erase operation. For example, in this state, the write operation of the sub-block SB0 is executed. Then, data is written sequentially from the cell unit CU of the string unit SU0 of the memory cell array 100a coupled to the individual word line WLa0. The example of FIG. 14 (b) illustrates a state in which the cell unit CU of the string unit SU0 of the memory cell array 100a coupled to the individual word line WLa63 is selected. As described above, also in the write operation of the sub-block SB0, similarly to the write operation of the sub-block SB1, the cell unit CU in the data writing state may exist on the bit line BL side and the source line SL side of the selected cell unit CU.

### 1.3.5.2 Voltage of Each Interconnect in Write Operation

Next, the voltage of each interconnect in the write operation will be described with reference to FIG. 15. FIG. 15 is a timing chart illustrating the voltage of each interconnect in the write operation of the sub-block SB0. The example of FIG. 15 shows one program loop.

As illustrated in FIG. 15, voltages applied to the non-selected word lines WL_unsel_e, WL_unsel_p, WL_unsel_pa, and WL_unsel_pb, the select gate lines SGD and SGS, and the source line SL are similar to those in FIG. 13.

The voltages applied to the selected word line WL_sel in the period from the time T0 to the time T4 are similar to that in FIG. 13.

At the time T4, the row decoder 20 applies different voltages to the individual word line WL in a set of individual word lines WL (individual word lines WLa and WLb) corresponding to the selected word line WL_sel. The row decoder 20 applies the voltage Vpgm to the selected word line WL_sel (individual word line WL) on the selected array chip 3 side. In addition, the row decoder 20 applies the voltage Vpass_e to the selected word line WL_sel (individual word line WL) on the non-selected array chip 3 side. More specifically, for example, in a case where the individual word line WLa63 is selected, the row decoder 20 applies the voltage Vpagm to the individual word line WLa63, and applies the voltage Vpass_e to the individual word line WLb63 that is a set with the individual word lines WLa63. By applying the voltage Vpass_e (not applying the voltage Vpagm) to the individual word line WL on the non-selected array chip 3 side, the influence of the write disturbance on the non-selected array chip 3 side is reduced.

The voltage applied to the selected word line WL_sel during the period from the time T6 to the time T8 is similar to that in FIG. 13.

At the time T8, the row decoder 20 applies different voltages to the individual word lines WL in the set of individual word lines WL (individual word lines WLa and WLb) corresponding to the selected word line WL_sel. The row decoder 20 applies the voltage Vvfy to the selected word line WL_sel (individual word line WL) on the selected array chip 3 side. In addition, the row decoder 20 applies the voltage Vread to the selected word line WL_sel (individual word line WL) on the non-selected array chip 3 side. More specifically, for example, in a case where the individual word line WLa63 is selected, the row decoder 20 applies the voltage Vvfy to the individual word line WLa63, and applies the voltage Vread to the individual word line WLb63 that is a set with the individual word lines WLa63.

### 1.4 Effects According to Present Embodiment

With the configuration according to the present embodiment, reliability of the semiconductor memory device 1 can be improved. This effects will be described in detail.

For example, a method of stacking a plurality of memory cell arrays (array chips) in order to highly integrate a semiconductor memory device is known. In a case where the word lines WL of the memory cell arrays are separately coupled to the circuit chip, the number of the word lines WL coupled to the row decoder increases. The circuit scale of the row decoder increases as the number of memory cell arrays increases. Therefore, an area of the circuit chip increases.

On the other hand, with the configuration according to the present embodiment, a part of the plurality of word lines WL can be shared by the plurality of array chips 3 stacked above the circuit chip 4. That is, the common word line WLc can be provided. As a result, an increase in the circuit scale of the row decoder 20 can be suppressed. Therefore, it is possible to suppress an increase in an area of the chip of the semiconductor memory device 1.

Furthermore, with the configuration according to the present embodiment, some of the plurality of word lines can be individually provided in the plurality of array chips 3. That is, the individual word line WL can be provided. As a result, a part of the plurality of word lines WL coupled to the array chips 3 can be controlled for each array chip 3. In the write operation, different voltages can be applied to the individual word lines WL of the array chips 3. As a result, the influence of the write disturbance can be reduced. That is, a shift of the threshold voltage of the memory cell transistor MC due to the write disturbance can be suppressed. Therefore, erroneous reading can be suppressed, and reliability of the semiconductor memory device 1 can be improved.

### 1.5 Modifications of First Embodiment

Next, modifications of the first embodiment will be described. Hereinafter, differences from the first embodiment will be mainly described.

### 1.5.1 First Modification

First, a first modification of the first embodiment will be described. In the first modification, a case where the arrangement of the common word line WLc and the individual word line WL is different from that of the first embodiment will be described.

### 1.5.1.1 Circuit Configuration of Memory Cell Array

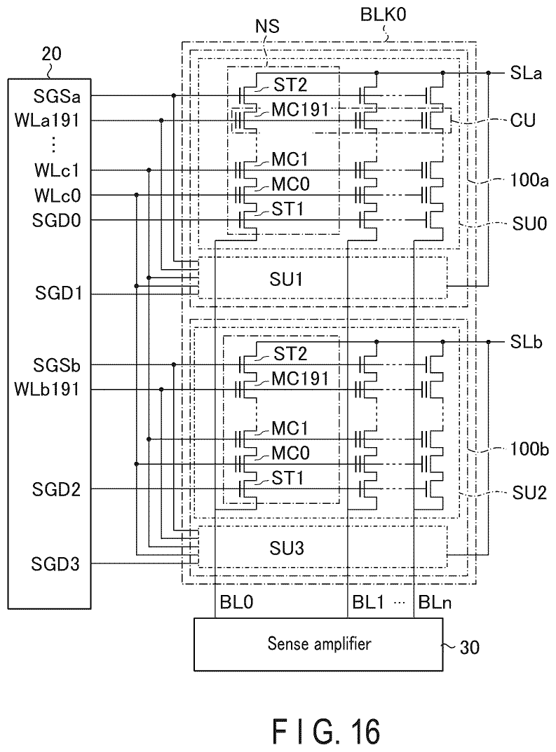

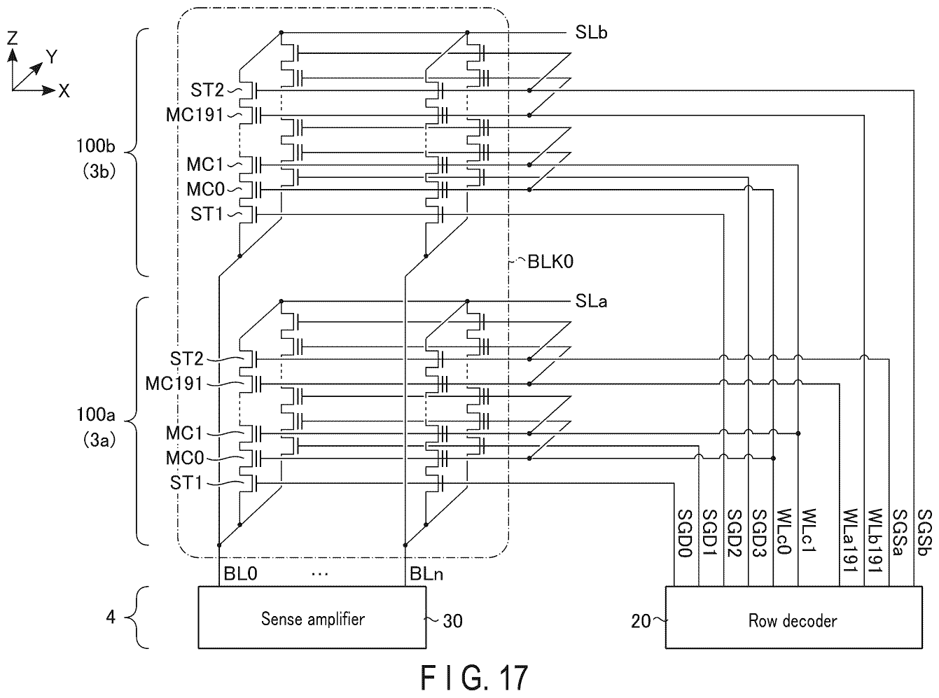

First, an example of a circuit configuration of the memory cell array 100 will be described with reference to FIGS. 16 and 17. FIG. 16 is a plan view illustrating a circuit configuration of the memory cell array 100. FIG. 17 is a perspective view illustrating a circuit configuration of the memory cell array 100. Note that the example of FIGS. 16 and 17 illustrate the circuit configuration of the block BLK0, but the same applies to the other blocks BLK.

As shown in FIGS. 16 and 17, in this example, the plurality of memory cell transistors MC0 of the string units SU0 and SU1 of the memory cell array 100a and the string units SU2 and SU3 of the memory cell array 100b are commonly coupled to the common word line WLc0. The plurality of memory cell transistors MC191 of the string units SU0 and SU1 of the memory cell array 100a are commonly coupled to the individual word line WLa191. The plurality of memory cell transistors MC191 of the string units SU2 and SU3 of the memory cell array 100b are commonly coupled to the individual word line WLb191. That is, the memory cell transistor MC disposed on the source line SL side of the NAND string NS is coupled to the individual word line WL, and the memory cell transistor MC disposed on the bit line BL side is coupled to the common word line WLc. Other configurations are similar to those in FIGS. 2 and 3 of the first embodiment.

### 1.5.1.2 Circuit Configuration of Row Decoder

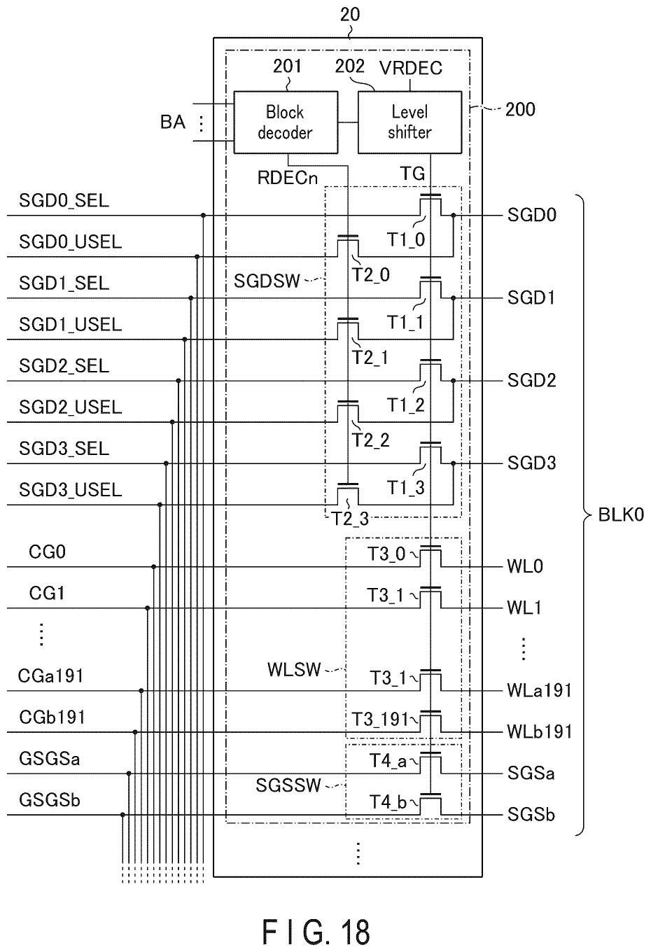

Next, a circuit configuration of the row decoder 20 will be described with reference to FIG. 18. FIG. 18 is a circuit diagram of the row decoder 20.

As illustrated in FIG. 18, the WL switch circuit group WLSW includes transistors T3_0, T3_1, T3_a191, and T3_b191. The number and the arrangement of the transistors T3 are designed based on the arrangement of the word lines WL.

One end of the transistor T3_0 is coupled to the common word line WLc0. The other end of the transistor T3_0 is coupled to the row driver 55 via an interconnect CG0. A gate of the transistor T3_0 is coupled to the signal line TG.

One end of the transistor T3_a191 is coupled to the individual word line WLa191. The other end of the transistor T3_a191 is coupled to the row driver 55 via the interconnect CGa191. A gate of the transistor T3_a191 is coupled to the signal line TG.

One end of the transistor T3_b191 is coupled to the individual word line WLb191. The other end of the transistor T3_b191 is coupled to the row driver 55 via an interconnect CGb191. A gate of the transistor T3_b191 is coupled to the signal line TG. That is, the individual word line WLa191 and the individual word line WLb191 are coupled to different switch circuits.

The row driver 55 applies a voltage corresponding to the selected block BLK to the interconnects CG0, CG1, CGa191, and CGb191.

Other circuit configurations are similar to those in FIG. 4 of the first embodiment.

### 1.5.1.3 Configuration of Block and Write State of Data

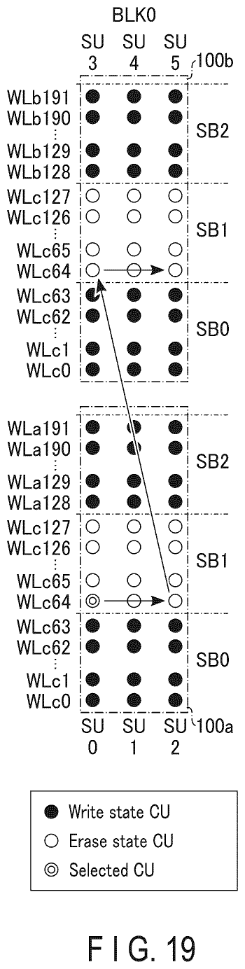

First, the configuration of the block BLK and the write state of data will be described with reference to FIG. 19. FIG. 19 is a diagram illustrating a configuration of the block BLK and a write state of data by the write operation of the sub-block SB1.

As shown in FIG. 19, the block BLK0 includes the six string units SU0 to SU5. The string units SU0 to SU2 are provided in the memory cell array 100a. The string units SU3 to SU5 are provided in the memory cell array 100b. The sub-blocks SB0 and SB1 share the word line WL. The sub-block SB2 does not share the word line WL.

More specifically, the string units SU0 to SU2 of the memory cell array 100a are coupled to the common word lines WLc0 to WLc127 and the individual word lines WLa128 to WLa191. The cell units CU corresponding to the common word lines WLc0 to WLc63 are included in the sub-block SB0. The cell units CU corresponding to the common word lines WLc64 to WLc127 are included in the sub-block SB1. The cell units CU corresponding to the individual word lines WLa128 to WLa191 are included in the sub-block SB2.

The string units SU3 to SU5 of the memory cell array 100b are coupled to the common word lines WLc0 to WLc127 and the individual word lines WLb128 to WLb191. The cell units CU corresponding to the common word lines WLc0 to WLc63 are included in the sub-block SB0. The cell units CU corresponding to the common word lines WLc64 to WLc127 are included in the sub-block SB1. The cell units CU corresponding to the individual word lines WLb128 to WLb191 are included in the sub-block SB2.

For example, in the write operation of the sub-block SB1, similarly to FIG. 12 (b) of the first embodiment, data is sequentially written from the cell unit CU of the string unit SU0 of the memory cell array 100a coupled to the common word line WLc64. In this case, the voltage described with reference to FIG. 13 of the first embodiment is applied to each interconnect.

### 1.5.2 Second Modification

Next, a second modification of the first embodiment will be described. In the second modification, a case where the arrangement of the common word lines WLc and the individual word lines WL is different from that of the first embodiment and the first modification of the first embodiment will be described.

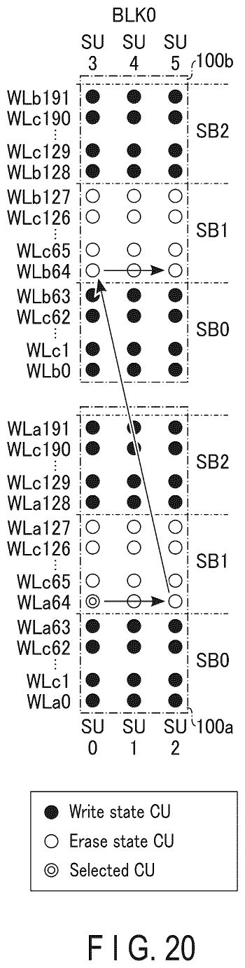

A specific example of the arrangement of the word lines WL will be described with reference to FIG. 20. FIG. 20 is a diagram illustrating a write state by the write operation of data of the sub-block SB1.

As shown in FIG. 20, the block BLK0 includes the six string units SU0 to SU5. The string units SU0 to SU2 are provided in the memory cell array 100a. The string units SU3 to SU5 are provided in the memory cell array 100b. In this example, the individual word lines WL are provided in the vicinity of the end portion of each sub-block SB, and the common word lines WL are provided in the central portion.

More specifically, for example, the string units SU0 to SU2 of the memory cell array 100a are coupled to the individual word lines WLa0, WLa63, WLa64, WLa127, WLa128, and WLa191, and the common word lines WLc1 to WLc62, WLc65 to WLc126, and WLc129 to WLc190. A cell units CU corresponding to the individual word lines WLa0 and WLa63 and the common word lines WLc1 to WLc62 are included in the sub-block SB0. The cell units CU corresponding to the individual word lines WLa64 and WLa127 and the common word lines WLc65 to WLc126 are included in the sub-block SB1. The cell units CU corresponding to the individual word lines WLa128 and WLa191 and the common word lines WLc129 to WLc190 are included in the sub-block SB2.

The string units SU3 to SU5 of the memory cell array 100b are coupled to the individual word lines WLb0, WLb63, WLb64, WLb127, WLb128, and WLb191, and the common word lines WLc1 to WLc62, WLc65 to WLc126, and WLc129 to WLc190. The cell units CU corresponding to the individual word lines WLb0 and WLb63 and the common word lines WLc1 to WLc62 are included in the sub-block SB0. The cell units CU corresponding to the individual word lines WLb64 and WLb127 and the common word lines WLc65 to WLc126 are included in the sub-block SB1. The cell units CU corresponding to the individual word lines WLb128 and WLb191 and the common word lines WLc129 to WLc190 are included in the sub-block SB2.

For example, in the write operation of the sub-block SB1, first, data is sequentially written from the cell unit CU of the string unit SU0 of the memory cell array 100a coupled to the individual word line WLa64. In the case of the write operation of the string unit SU0 coupled to the individual word line WLa64 to the cell unit CU, the voltage described with reference to FIG. 15 of the first embodiment is applied to each interconnect.

### 1.5.3 Effects According to Modifications of First Embodiment

With the configurations according to the first modification and the second modification, the same effects as those of the first embodiment can be obtained.

The write disturbance includes, in addition to a write disturbance due to an insufficient electric field between control gate and channel and a write disturbance in a case where the electric field between the control gate and the channel is too strong, a hot carrier injection type write disturbance in which due to a potential difference between the source and the drain of the memory cell transistor MC, hot carriers generated therebetween jump into the charge storage layer. For example, these are likely to occur in the memory cell transistor MC in the vicinity of the select gate lines SGD and SGS which are physically discontinuous in the NAND string NS, or in a portion where the characteristics of the memory cell transistor MC greatly change due to a change in the processed shape of the memory hole MH (for example, the diameter of the memory hole MH). Therefore, even in the vicinity of the end portion of the sub-block SB, there is a possibility that it is likely to occur physically or electrically. On the other hand, in the configuration according to the second modification of the first embodiment, the individual word lines WL can be provided in the vicinity of the end of the sub-block SB. As a result, the write disturbance can be suppressed.

### 2. Second Embodiment

Next, a second embodiment will be described. In the second embodiment, different write orders will be described. Hereinafter, differences from the first embodiment will be mainly described.

### 2.1 Memory Address

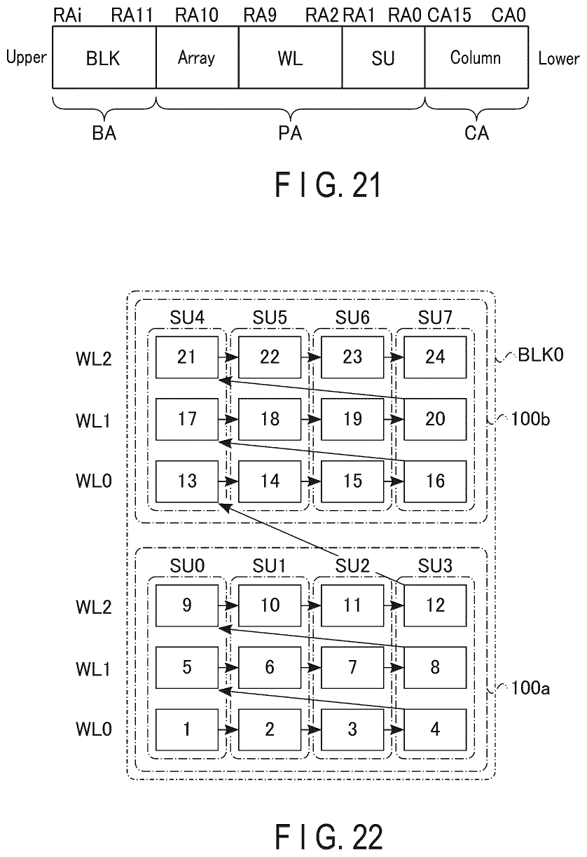

First, an example of a memory address ADD will be described with reference to FIG. 21. FIG. 21 is a configuration diagram of the memory address ADD.

As illustrated in FIG. 21, the memory address ADD includes a block address BA, a page address PA, and a column address CA. In the example of FIG. 21, the page address PA includes a string unit address, a word line address, and an array address from the lower address side. The example of FIG. 21 does not include a sub-block address.

In this example, the array address is located above the word line address. Therefore, for example, in a state where an array chip 3a is selected in the array address, the word line address is incremented. Then, after the word line address is incremented to the end, the array address is incremented, and the array chip 3a is selected. Therefore, a memory cell array 100b is selected after the writing in a memory cell array 100a is completed.

### 2.2 Writing Order of Data

Next, an example of the writing order of data will be described with reference to FIG. 22. FIG. 22 is a diagram illustrating the writing order of data based on the memory address ADD illustrated in FIG. 21.

As shown in FIG. 21, a block BLK0 includes eight string units SU0 to SU7. The string units SU0 to SU3 are provided in the memory cell array 100a. The string units SU4 to SU7 are provided in the memory cell array 100b. In the example of FIG. 22, the block BLK0 includes word lines WL0 to WL2.

For example, first, in a state where the array chip 3a (memory cell array 100a) and the word line WL0 are selected, the string unit address of the lower address is incremented. That is, the string units SU0 to SU3 of the memory cell array 100a are sequentially selected (write order “1” to “4”). Next, the word line address is incremented, and the word line WL1 is selected. In this state, the string unit address is incremented. That is, the string units SU0 to SU3 are sequentially selected (write order “5” to “8”). Next, the word line address is incremented. As a result, the word line WL2 is selected. In this state, the string unit address is incremented. That is, the string units SU0 to SU3 are sequentially selected (write order “9” to “12”). In a case where the word line address is incremented to the end, the array address which is the upper address is incremented. As a result, the array chip 3b is selected. In other words, the memory cell array 100b is selected after the write operation in the memory cell array 100a is completed. Similarly to the array chip 3a, first, the string unit address is incremented in a state where the word line WL0 is selected. That is, the string units SU4 to SU7 are sequentially selected (write order “13” to “16”). Next, the word line address is incremented, and the word line WL1 is selected. In this state, the string unit address is incremented. That is, the string units SU4 to SU7 are sequentially selected (write order “17” to “20”). Next, the word line address is incremented. As a result, the word line WL2 is selected. In this state, the string unit address is incremented. That is, the string units SU4 to SU7 are sequentially selected (write order “21” to “24”). As a result, the write operation in the memory cell array 100b ends.

### 2.3 Specific Example of Block Configuration and Write State of Data

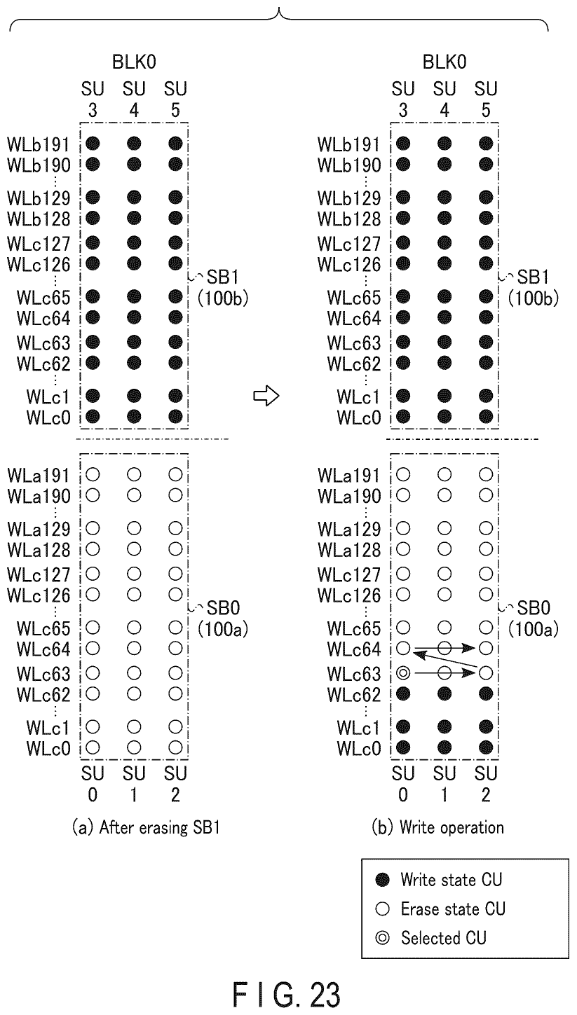

Next, a specific example of the configuration of a block BLK and the write state of data will be described with reference to FIG. 23. FIG. 23 is a diagram illustrating a configuration of the block BLK and a change in a write state by the write operation of data of a sub-block SB0.

As shown in FIG. 23, the block BLK0 includes six string units SU0 to SU5. The string units SU0 to SU2 are provided in the memory cell array 100a. The string units SU3 to SU5 are provided in the memory cell array 100b. Each of the memory cell arrays 100a and 100b is provided with 192 word lines WL0 to WL191.

More specifically, for example, the memory cell array 100a is set to the sub-block SB0. The string units SU0 to SU2 of the memory cell array 100a are coupled to common word lines WLc0 to WLc127 and individual word lines WLa128 to WLa191. That is, the word lines WLa128 to WLa191 are provided on a source line SL side.

The memory cell array 100b is set in the sub-block SB1. The string units SU3 to SU5 of the memory cell array 100b are coupled to the common word lines WLc0 to WLc127 and the individual word lines WLb128 to WLb191. That is, the individual word lines WLb128 to WLb191 are provided on the source line SL side.

FIG. 23 (a) illustrates a state in which the data of the sub-block SB0, that is, the memory cell array 100a is erased by the sub-block erase operation. For example, in this state, the write operation of the sub-block SB0 is executed. Then, data is written sequentially from the cell unit CU of the string unit SU0 coupled to the common word line WLc0. The example of FIG. 23 (b) illustrates a state in which the cell unit CU of the string unit SU0 coupled to the common word line WLc63 is selected.

As illustrated in FIG. 23 (b), in a case where the write operation of the sub-block SB0 is executed, a sub-block SB1 (array chip 3b) side may be in a state where data has been written. In such a case, in order to suppress the write disturbance in the non-selected array chip 3b, the voltage described with reference to FIGS. 13 and 15 of the first embodiment is applied to each interconnect. More specifically, in the write operation of the sub-block SB0, in a case where the cell unit CU coupled to one of the common word lines WLc0 to WLc127 is a program target, the voltage described with reference to FIG. 13 of the first embodiment is applied to each interconnect. In a case where the cell unit CU coupled to one of the individual word lines WLa127 to WLa191 is a program target, the voltage described with reference to FIG. 15 of the first embodiment is applied to each interconnect. The same applies to the write operation of the sub-block SB1.

### 2.4 Effects According to Present Embodiment

The configuration according to the present embodiment provides the same effects as those of the first embodiment.

### 2.5 Modifications of Second Embodiment

Next, a modification of the second embodiment will be described. Hereinafter, differences from the second embodiment will be mainly described.

### 2.5.1 First Modification

First, a first modification of the second embodiment will be described. In the first modification, a case where the arrangement of the common word line WLc and the individual word line WL is different from that of the second embodiment will be described.

### 2.5.1.1 Cross-Sectional Configuration of Memory Cell Array

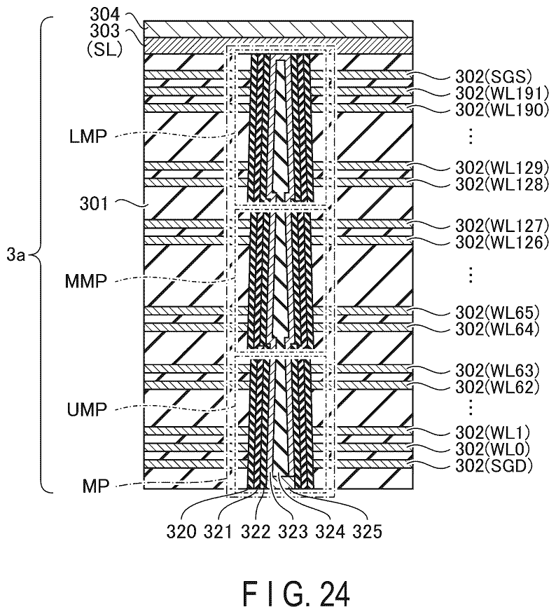

First, an example of a cross-sectional configuration of a memory cell array 100 will be described with reference to FIG. 24. FIG. 24 is a cross-sectional view of the memory cell array 100. The example of FIG. 24 illustrates one memory pillar MP of the array chip 3a. Note that the configuration of the memory pillar MP of the array chip 3b is similar. In the example of FIG. 24, some of a plurality of interconnect layers 302 are omitted.

As illustrated in FIG. 24, for example, the memory pillar MP includes three memory pillars LMP, MMP, and UMP. The memory pillars LMP, MMP, and UMP are stacked in a Z1 direction to constitute one memory pillar MP.

The memory pillar LMP has a substantially columnar shape. The memory pillar LMP extends in a Z direction. The memory pillar LMP penetrates (passes) the plurality of interconnect layers 302 each functioning as the word lines WL128 to WL191 and a select gate line SGS. An end of the memory pillar LMP in a Z2 direction is in contact with a semiconductor layer (source line SL) 303.

The memory pillar MMP has a substantially columnar shape. The memory pillar MMP extends in the Z direction. The memory pillar MMP penetrates (passes) the plurality of interconnect layers 302 each functioning as the word lines WL64 to WL127. An end of the memory pillar LMP in the Z2 direction is in contact with the memory pillar LMP.

The memory pillar UMP has a substantially columnar shape. The memory pillar UMP extends in the Z direction. The memory pillar UMP penetrates (passes) the plurality of interconnect layers 302 each functioning as a select gate line SGD and the word lines WL0 to WL63. An end of the memory pillar UMP in the Z2 direction is in contact with the memory pillar UMP.

For example, the word lines WL0, WL63, WL64, WL127, WL128, and WL191 located at the ends of the memory pillars LMP, MMP, and UMP are individual word lines WLa. Then, the word lines WL1 to WL62, WL65 to WL126, and WL129 to WL190 located at the centers of the memory pillars LMP, MMP, and UMP are common word line WLc.

### 2.5.1.2 Specific Example of Block Configuration and Write State of Data

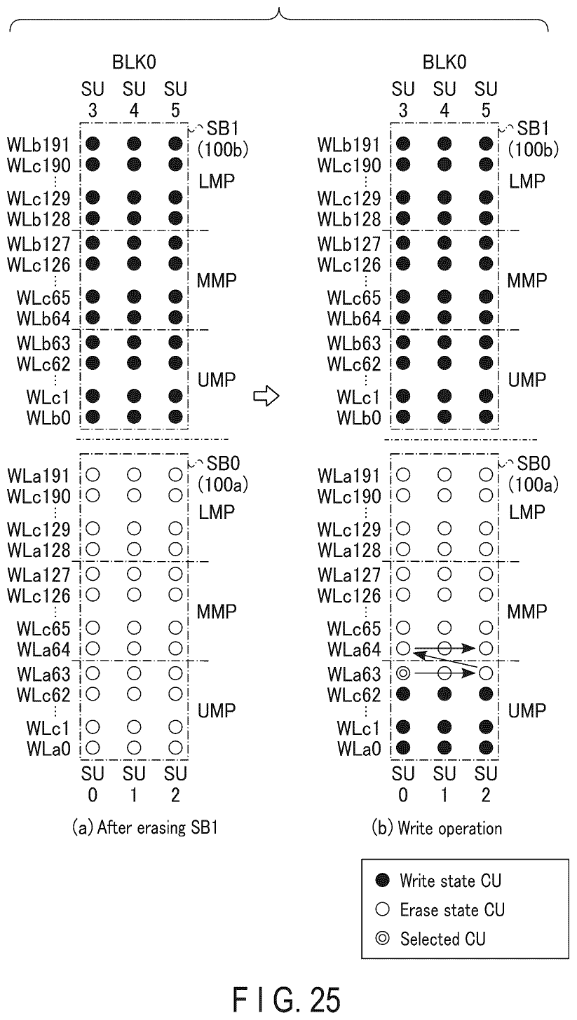

Next, a specific example of the configuration of the block BLK and the write state of data will be described with reference to FIG. 25. FIG. 25 is a diagram illustrating a configuration of the block BLK and a change in a write state of data by the write operation of the sub-block SB0.

As illustrated in FIG. 25, in this example, the individual word lines WL are provided in the vicinity of the end portions of the memory pillars LMP, MMP, and UMP, and the common word lines WL are provided in the central portion.

More specifically, for example, the string units SU0 to SU2 of the memory cell array 100a are coupled to the individual word lines WLa0, WLa63, WLa64, WLa127, WLa128, and WLa191, and the common word lines WLc1 to WLc62, WLc65 to WLc126, and WLc129 to WLc190.

The string units SU3 to SU5 of the memory cell array 100b are coupled to the individual word lines WLb0, WLb63, WLb64, WLb127, WLb128, and WLb191, and the common word lines WLc1 to WLc62, WLc65 to WLc126, and WLc129 to WLc190.

Similarly to the second embodiment, in the write operation of the sub-block SB0, in a case where the cell unit CU coupled to one of the common word lines WLc1 to WLc62, WLc65 to WLc126, and WLc129 to WLc190 is a program target, the voltage described with reference to FIG. 13 of the first embodiment is applied to each interconnect. In a case where the cell unit CU coupled to one of the individual word lines WLa0, WLa63, WLa64, WLa127, WLa128, and WLa191 is a program target, the voltage described with reference to FIG. 15 of the first embodiment is applied to each interconnect. The same applies to the write operation of the sub-block SB1.

### 2.5.2 Second Modification

Next, a second modification of the second embodiment will be described. In the second modification, a case where the arrangement of the common word lines WLc and the individual word lines WL is different from those of the second embodiment and the first modification of the second embodiment will be described.

### 2.5.2.1 Circuit Configuration of Memory Cell Array

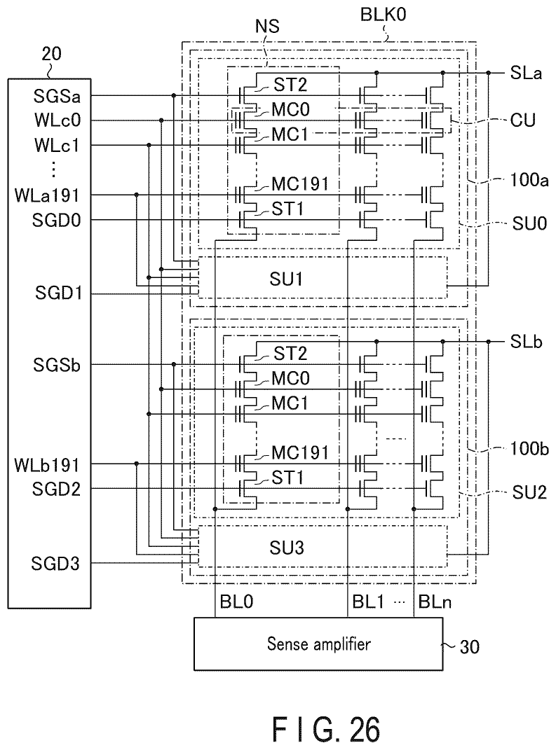

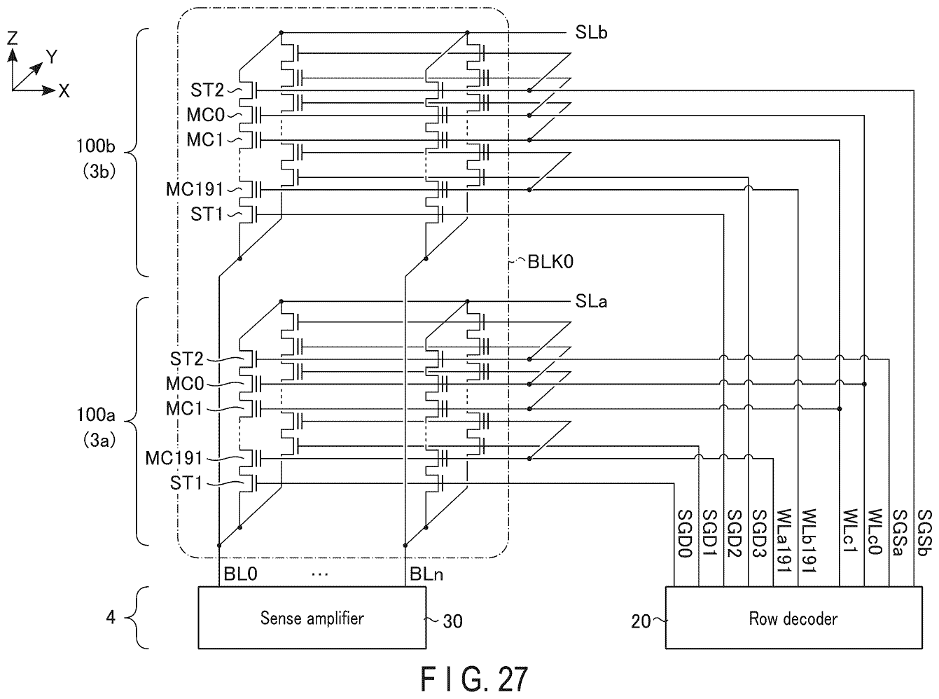

First, an example of a circuit configuration of the memory cell array 100 will be described with reference to FIGS. 26 and 27. FIG. 26 is a plan view illustrating the circuit configuration of the memory cell array 100. FIG. 27 is a perspective view illustrating the circuit configuration of the memory cell array 100. Note that the example of FIGS. 26 and 27 illustrate the circuit configuration of the block BLK0, but the same applies to the other blocks BLK.

As illustrated in FIGS. 26 and 27, in this example, the current paths of the selection transistor ST2, the memory cell transistors MC0 to MC191, and the selection transistor ST1 are coupled in series in this order. That is, the selection transistor ST2, the memory cell transistors MC0 to MC191, and the selection transistor ST1 are sequentially coupled from the source lines SL toward the bit lines BL.

The plurality of memory cell transistors MC0 of the string units SU0 and SU1 of the memory cell array 100a and the string units SU2 and SU3 of the memory cell array 100b are commonly coupled to the common word line WLc0. The plurality of memory cell transistors MC1 of the string units SU0 and SU1 of the memory cell array 100a and the string units SU2 and SU3 of the memory cell array 100b are commonly coupled to the common word line WLc1. The plurality of memory cell transistors MC191 of the string units SU0 and SU1 of the memory cell array 100a are commonly coupled to the individual word line WLa191. The plurality of memory cell transistors MC191 of the string units SU2 and SU3 of the memory cell array 100b are commonly coupled to the individual word line WLb191. That is, the memory cell transistors MC disposed on the source line SL side of the NAND string NS are coupled to the common word lines WLc, and the memory cell transistors MC disposed on the bit lines BL side are coupled to the individual word lines WL. Other configurations are similar to those in FIGS. 2 and 3 of the first embodiment.

### 2.5.2.2 Specific Example of Block Configuration and Write State of Data

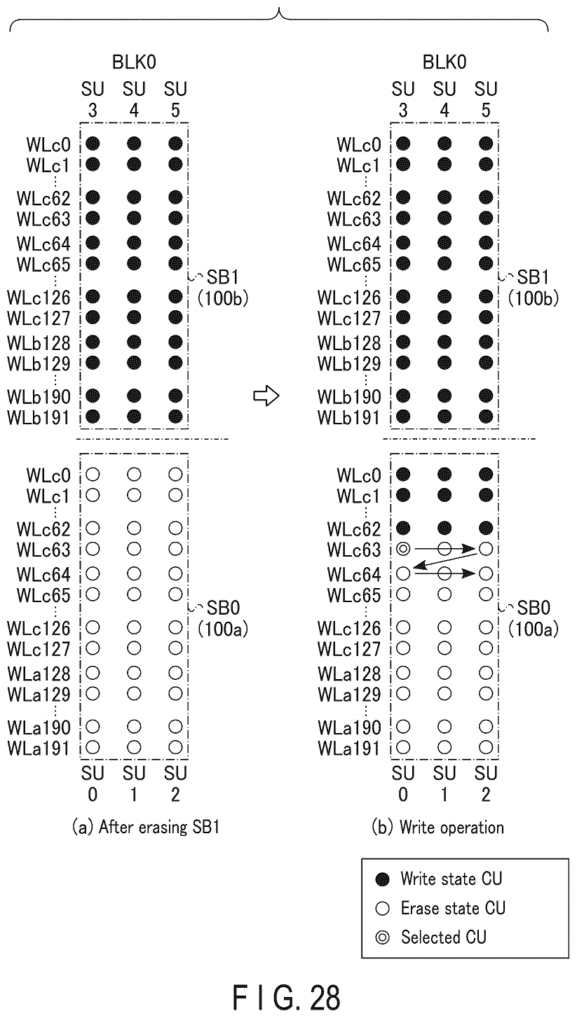

Next, a specific example of the configuration of the block BLK and the write state of data will be described with reference to FIG. 28. FIG. 28 is a diagram illustrating a configuration of the block BLK and a change in a write state of data by the write operation of the sub-block SB0.

As shown in FIG. 28, in this example, the string units SU0 to SU2 of the memory cell array 100a are coupled to the common word lines WLc0 to WLc127 and the individual word lines WLa128 to WLa191. That is, the individual word lines WLa128 to WLa191 are provided on the bit line BL side.

The string units SU3 to SU5 of the memory cell array 100b are coupled to the common word lines WLc0 to WLc127 and the individual word lines WLb128 to WLb191. That is, the individual word lines WLb128 to WLb191 are provided on the bit line BL side.

Similarly to the second embodiment, in the write operation of the sub-block SB0, in a case where the cell unit CU coupled to one of the common word lines WLc0 to WLc127 is a program target, the voltage described with reference to FIG. 13 of the first embodiment is applied to each interconnect. In a case where the cell unit CU coupled to one of the individual word lines WLa128 to WLa191 is a program target, the voltage described with reference to FIG. 15 of the first embodiment is applied to each interconnect. The same applies to the write operation of the sub-block SB1.

### 2.5.3 Effects According to Present Embodiment

The configuration according to the present embodiment provides the same effects as those of the second embodiment.

### 3. Others

The semiconductor memory device according to the above embodiments includes a first chip (3a), a second chip (3b), and third chip (4). The first chip includes a first pillar (MP) including a first memory cell (MC63) and a second memory cell (MC64) coupled in series, a first bit line (BL) coupled to one end of the first pillar, and a first source line (SL) coupled to another end of the first pillar. The second chip includes a second pillar (MP) including a third memory cell (MC63) and a fourth memory cell (MC64) coupled in series, a second bit line (BL) coupled to one end of the second pillar, and a second source line (SL) coupled to another end of the second pillar. The third chip includes a sense amplifier (30) to which the first bit line and the second bit line are commonly coupled and a row decoder (20) to which a first word line (WLa63), a second word line (WLb63), and a third word line (WLc64) are coupled. The first word line is coupled to a gate of the first memory cell. The second word line is coupled to a gate of the third memory cell. The third word line is coupled to gates of the second memory cell and the fourth memory cell.

By applying the above embodiments, it is possible to provide a semiconductor memory device capable of improving reliability.

Note that the embodiment is not limited to the above-described embodiments, and various modifications are possible.

The “coupling” in the above embodiment also includes a state of being coupled indirectly, for example, with a transistor or a resistor interposed therebetween.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first chip including:
a first pillar including a first memory cell and a second memory cell coupled in series;
a first bit line coupled to one end of the first pillar; and
a first source line coupled to another end of the first pillar;
a second chip including:
a second pillar including a third memory cell and a fourth memory cell coupled in series;
a second bit line coupled to one end of the second pillar; and
a second source line coupled to another end of the second pillar; and
a third chip including:
a sense amplifier to which the first bit line and the second bit line are commonly coupled; and
a row decoder to which a first word line, a second word line, and a third word line are coupled, the first word line being coupled to a gate of the first memory cell, the second word line being coupled to a gate of the third memory cell, and the third word line being coupled to gates of the second memory cell and the fourth memory cell.

2. The semiconductor memory device according to claim 1, wherein
in a write operation of the first memory cell, the row decoder applies a first voltage to the first word line, a second voltage to the second word line, and a third voltage to the third word line, the second voltage being lower than the first voltage, the third voltage being lower than the first voltage.

3. The semiconductor memory device according to claim 2, wherein
the first pillar further includes a fifth memory cell coupled in series with the first memory cell and the second memory cell,
the second pillar further includes a sixth memory cell coupled in series with the third memory cell and the fourth memory cell,
a gate of the fifth memory cell is coupled to the row decoder via a fourth word line,
a gate of the sixth memory cell is coupled to the row decoder via a fifth word line, and
in the write operation of the first memory cell, the row decoder applies a fourth voltage to the fourth word line and a fifth voltage to the fifth word line, the fourth voltage being lower than the first voltage, the fifth voltage being higher than the fourth voltage and lower than the first voltage.

4. The semiconductor memory device according to claim 3, wherein
in the write operation of the first memory cell, the row decoder applies, in a first period, a sixth voltage to the second word line and a seventh voltage higher than the sixth voltage to the third to fifth word lines, and then, in a second period, applies the second voltage to the second word line, the third voltage to the third word line, the fourth voltage to the fourth word line, and the fifth voltage to the fifth word line.

5. The semiconductor memory device according to claim 1, wherein
in a write operation of the second memory cell, the row decoder applies an eighth voltage to the third word line, a ninth voltage to the first word line, and a tenth voltage to the second word line, the ninth voltage being lower than the eighth voltage, the tenth voltage being higher than the ninth voltage and lower than the eighth voltage.

6. The semiconductor memory device according to claim 5, wherein
the first pillar further includes a seventh memory cell coupled in series with the first memory cell and the second memory cell,
the second pillar further includes an eighth memory cell coupled in series with the third memory cell and the fourth memory cell,
a gate of the seventh memory cell and a gate of the eighth memory cell are commonly coupled to the row decoder via a sixth word line, and
in the write operation of the second memory cell, the row decoder applies an eleventh voltage to the sixth word line, the eleventh voltage being higher than the ninth voltage and lower than the tenth voltage.

7. The semiconductor memory device according to claim 1, wherein
the third chip further includes a driver circuit that supplies a voltage to the row decoder, and
the row decoder includes:
a first switch circuit coupled between the first word line and the driver circuit;
a second switch circuit coupled between the second word line and the driver circuit; and
a third switch circuit coupled between the third word line and the driver circuit.

8. The semiconductor memory device according to claim 1, wherein
the first pillar further includes a first selection transistor coupled in series with the first memory cell and the second memory cell, and having a gate coupled to the row decoder via a first select gate line, and
the second pillar further includes a second selection transistor coupled in series with the third memory cell and the fourth memory cell, and having a gate coupled to the row decoder via a second select gate line.

9. The semiconductor memory device according to claim 8, wherein
in the write operation of the first memory cell, the row decoder applies a twelfth voltage to the first select gate line and a thirteenth voltage to the second select gate line, the thirteenth voltage being lower than the twelfth voltage.

10. The semiconductor memory device according to claim 1, wherein
the write operation includes a program operation and a program verify operation, and
in the program verify operation in the write operation of the first memory cell, the row decoder applies a fourteenth voltage to the first word line, a fifteenth voltage to the second word line, and a sixteenth voltage to the third word line, the fifteenth voltage being higher than the fourteenth voltage, the sixteenth voltage being higher than the fourteenth voltage.

11. The semiconductor memory device according to claim 1, wherein
the write operation includes a program operation and a program verify operation, and
in the program verify operation in the write operation of the second memory cell, the row decoder applies a seventeenth voltage to the third word line and an eighteenth voltage to the first word line and the second word line, the eighteenth voltage being higher than the seventeenth voltage.

12. The semiconductor memory device according to claim 1, wherein
the first pillar and the second pillar extend in a first direction, and are arranged side by side in the first direction.

13. The semiconductor memory device according to claim 1, wherein
the second chip is bonded to a first surface of the first chip, and the third chip is bonded to a second surface of the first chip facing the first surface.
